(19) United States
(12) Patent Application Publication
(10) Pub. No.: US 2016/0260627 A1
(43) Pub. Date: Sep. 8, 2016

(54) DOOR OPENING AND CLOSING APPARATUS, TRANSFER APPARATUS, AND STORAGE CONTAINER OPENING METHOD

(71) Applicant: SINFONIA TECHNOLOGY CO., LTD., Tokyo (JP)

(72) Inventor: Takaaki Nakano, Tokyo (JP)

(73) Assignee: SINFONIA TECHNOLOGY CO., LTD., Tokyo (JP)

(21) Appl. No.: 15/057,326

(22) Filed: Mar. 1, 2016

(30) Foreign Application Priority Data
Mar. 6, 2015 (JP) 2015-044849

(51) Int. Cl. H01L 21/673; H01L 21/677

(52) U.S. Cl. CPC H01L 21/67389; H01L 21/67772

(57) ABSTRACT

A door opening and closing apparatus includes: a frame that structures part of a wall surface of a transfer room and is provided with an opening for opening the transfer room; a door part capable of opening and closing the opening: a placing pedestal on which a storage container can be placed; a chamber provided at a position on the transfer room side so as to face the opening, and having an inner space to be subjected to a purge process with an environmental gas; and a pressure adjusting part causing the inner space of the chamber and the inner space of the storage container to communicate with each other using a route other than the opening. The door opening and closing apparatus can be applied to a wafer transfer apparatus or the like.

### BACKGROUND OF THE INVENTION

(1) Field of the Invention

The present invention relates to a door opening and closing apparatus having a chamber disposed in an adjacent transfer room, a transfer apparatus having the door opening and closing apparatus, and a storage container opening method.

(2) Description of Related Art

In a semiconductor manufacturing process, wafers are processed in a clean room for improving yields and quality. However, with today's highly integrated devices, miniaturized circuitry, and wafers of increased sizes, it has been becoming difficult to manage fine dust in the entire clean room, in terms of both costs and techniques. Therefore, in recent years, “the minienvironment system” is employed replacing the method for improving the cleanliness of the entire clean room. In the minienvironment system, the cleanliness of only a local space around wafers is improved, and processes of transferring wafers and others are performed. In the minienvironment system, a door opening and closing apparatus is provided adjacent to a transfer room. The door opening and closing apparatus structures part of the wall surface of a wafer transfer room which is substantially closed inside a case. On the door opening and closing apparatus, a storage container (e.g., a storage container called Front-Opening Unified Pod: FOUP) storing transfer target objects in a highly clean inner space is placed. The door opening and closing apparatus has a door part which opens and closes a lid part of the storage container while being closely attached to the lid part.

Such a door opening and closing apparatus is an apparatus for putting in and taking out transfer target objects to and from the transfer room, and functions as an interface part to the storage container. Then, in the state where the door part of the door opening and closing apparatus is closely attached to the lid part provided at the front surface of the storage container, when the door part and the lid part are opened simultaneously, a transfer robot provided in the transfer room takes out the transfer target objects from inside the storage container to inside the transfer room. Alternatively, the transfer robot takes out the transfer target objects from inside the transfer room and stores them inside the storage container through the door opening and closing apparatus.

In recent years, integration and miniaturization of devices are highly increasingly pursued. It is demanded to maintain a higher level of cleanliness around the transfer target objects such as wafers, in order to avoid particles or moisture from attaching to the surface of the transfer target objects. Further, in order to prevent any changes, such as oxidation, at the surface of the transfer target objects, it is also practiced to place the transfer target objects in an atmosphere of nitrogen being an inert gas, or under vacuum.

In order to properly maintain an ambient atmosphere of the transfer target object, as disclosed in JP 2012-19046 A, there is also devised and brought into practical use a door opening and closing apparatus having a function of purging inside a sealable storage pod type storage container (e.g., the FOUP) with an environmental gas such as nitrogen or dry air.

Further, it has also been practiced to prevent contamination of the surface of the transferred transfer target objects with particles and the like, by establishing a highly clean atmosphere by introducing air cleaned through a chemical filter or the like into the wafer transfer room. Further, similarly to the storage container, a dry nitrogen atmosphere may be established in the transfer room. Still further, such a gas atmosphere may be any appropriate special gas (hereinafter generally referred to as the “environmental gas”) other than dry nitrogen, so as to correspond to the process for the transfer target objects.

Still further, it is also proposed to dispose a chamber covering the door part in the transfer room, and to purge inside the chamber with the environmental gas (e.g., JP 2014-116441 A).

When a purge process on the inner space of the chamber is performed with the environmental gas in the state where the inner space of the storage container is sealed by the lid part, the pressure of the inner space of the chamber rises and attains positive pressure. Further, when the pressure of the inner space of the chamber becomes higher than the pressure of the inner space of the storage container, the force acting in the direction pressing the door part against the storage container becomes great. Accordingly, the force required in the process of shifting the door part toward the chamber and opening the inner space of the storage container to the inner space of the chamber (a storage container opening process) becomes also great. As a result, there arises a problem that the storage container opening process cannot be smoothly and properly carried out, or the door part and the lid part cannot be shifted at all, making it impossible to open the inner space of the storage container.

Provided that the door part is forcibly shifted under such conditions and the storage container opening process is carried out, the shock of the process causes the entire door opening and closing apparatus to wobble or vibrate. Then, particles may rise and the transfer target objects stored in the storage container on the placing pedestal may be displaced. Further, forcible execution of the storage container opening process may invite failure or damage of the door part or the lid part.

In order to avoid such problems, it may be contemplated temporarily stopping the purge process on the inner space of the chamber to reduce the pressure of the inner space of the chamber, and thereafter shifting the door part to the chamber side to execute the storage container opening process. However, there is no denying that a reduction in the processing efficiency is invited by the temporary stop of the purge process on the inner space of the chamber.

### SUMMARY OF THE INVENTION

The present invention has been made in view of the above-mentioned problems, and a chief object of the present invention is to provide a door opening and closing apparatus with which a process of shifting a door part and opening the inner space of a storage container to the inner space of a chamber can be carried out smoothly and properly without the necessity of temporarily stopping the purge process on the inner space of the chamber, while avoiding rising of particles and displacement of transfer target objects stored in a storage container on a placing pedestal associated with the opening process. Another object of the present invention is to provide a transfer apparatus such as an EFEM (Equipment Front End Module) having the door opening and closing apparatus. Still another object of the present invention is to provide a storage container opening method.

That is, the present invention relates to a door opening and closing apparatus provided adjacent to a transfer room for putting in and taking out a transfer target object to and from between a storage container capable of storing the transfer target object in an inner space thereof and the transfer room. Here, the transfer target object in the present invention may be a wafer, a reticle, a liquid crystal substrate, a glass substrate, a culture plate, a culture vessel, a dish, a petri dish and the like, and the present invention is applicable to the technique of transferring the transfer target object in a container in various fields such as semiconductors, liquid crystals, cell cultivations and the like. Further, “the transfer room” in the present invention is a room for transferring the transfer target object. For example, when the transfer target object is a wafer, the transfer room is “the wafer transfer room”.

Then, the door opening and closing apparatus of the present invention includes: a plate-like frame that structures part of a wall surface of the transfer room and is provided with an opening for opening the transfer room; a door part capable of opening and closing the opening; a placing pedestal on which the storage container can be placed; a chamber provided at a position on the transfer room side so as to face the opening and having an inner space to be subjected to a purge process with an environmental gas; and a pressure adjusting part causing the inner space of the chamber and the inner space of the storage container to communicate with each other using a route other than the opening.

With the door opening and closing apparatus of the present invention, the environmental gas with which the chamber is filled by the purge process can be introduced into the inner space of the storage container through the pressure adjusting part. This eliminates the pressure difference between the inner space of the chamber and the inner space of the storage container. As a result, as compared to the structure in which the pressure in the chamber becomes higher than the pressure in the storage container, the force required for shifting the door part toward the chamber and opening the inner space of the storage container to the inner space of the chamber (the storage container opening process) can be reduced. Then, the storage container opening process can be performed smoothly and properly. Additionally, since any shock associated with the opening process can be prevented or suppressed, various problems such as wobbling or vibration of the entire door opening and closing apparatus, rising of particles, or displacement of the transfer target object stored in the storage container on the placing pedestal can be entirely prevented or suppressed. Further, with the door opening and closing apparatus of the present invention, even during the purge process on the inner space of the chamber, the pressure difference between the chamber and the storage container can be eliminated. Accordingly, it is not necessary to temporarily stop the purge process on the inner space of the chamber in order to reduce the pressure of the inner space of the chamber, and therefore it is advantageous also in the purge process efficiency.

The pressure adjusting part of the present invention is just required to cause the inner space of the chamber and the inner space of the storage container to communicate with each other using a route other than the opening formed at the frame. A suitable specific example may be a pressure adjusting part which includes a gas discharge part configured to discharge the environmental gas supplied into the inner space of the chamber to the outside of the chamber, a gas discharge route having an upstream end coupled to the gas discharge part, and a gas introduction part coupled to a downstream end of the gas discharge route and configured to introduce the environmental gas into the inner space of the storage container via the gas discharge route.

In particular, with the door opening and closing apparatus including a bottom purge part capable of replacing a gas atmosphere in the storage container by the environmental gas using a plurality of nozzles provided at predetermined positions on the placing pedestal, a structure in which the gas introduction part is structured by a dedicated nozzle separately provided from the nozzles can be employed. Alternatively, a structure in which among a plurality of nozzles, a predetermined number of nozzles function as the gas introduction part can be employed.

In the mode where a dedicated nozzle is used, all the nozzles of the bottom purge part are used for the bottom purge-purpose. Accordingly, as compared to the latter mode, the pressure difference between the chamber and the storage container can be eliminated by the gas introduction part-nozzle while achieving the intended purge function as the bottom purge part. Further, in the mode where the existing (already provided) nozzles are used, since the bottom purge part-nozzles previously provided on the placing pedestal are used as the gas introduction part-nozzles, it is not necessary to newly provide nozzles for the gas introduction part separately from the nozzles of the bottom purge part. Therefore, a reduction in the number of components and costs can be achieved. Note that, as the latter mode of using the existing nozzles, either the structure in which all the nozzles functioning as the purge gas injection nozzles among the plurality of bottom purge nozzles are caused to function as the gas introduction part or the structure in which not all but only a predetermined number of nozzles among the nozzles functioning as the purge gas injection nozzles are caused to function as the gas introduction part can be employed.

Further, a transfer apparatus of the present invention includes a transfer room, the door opening and closing apparatus structured as described above and provided on a wall surface of the transfer room, and a transfer robot provided in the transfer room and being capable of putting in and taking out the transfer target object to and from between the storage container on the placing pedestal of the door opening and closing apparatus and the transfer room.

A storage container opening method of the present invention relates to a storage container opening method using the above-described door opening and closing apparatus. The method includes: performing a purge process with an environmental gas on the inner space of the chamber in a state where the storage container is placed on the placing pedestal of the door opening and closing apparatus, the storage container having an inner space sealed by a lid part; introducing the environmental gas in the chamber into the inner space of the storage container, from the inner space of the chamber having undergone the purge process, by the pressure adjusting part using the route other than the opening, to equalize a pressure of the inner space of the storage container to the pressure of the inner space of the chamber by a pressure adjusting process; and subsequently shifting the lid part together with the door part, to cause the inner space of the storage container to open to the inner space of the chamber via the opening of the frame.

With such a storage container opening method, in the structure in which the chamber is disposed on the transfer room side and the inner space of the chamber is subjected to the purge process with the environmental gas in order to reduce the space with which the inner space of the storage container communicates when the storage container is opened to thereby maintain the purge concentration in the storage container, after the pressure is adjusted by pressure adjusting process, the lid part is shifted together with the door part, and the inner space of the storage container is opened to the inner space of the chamber via the opening of the frame. Thus, the above-described operation and effect can be obtained, and the opening process can be carried out smoothly and properly. Further, rising of particles or displacement of the transfer target object in the storage container attributed to the shock associated with the opening process can be prevented or suppressed.

According to the present invention, by equalizing the pressure in the chamber to the pressure in the storage container in the state where the storage container on the placing pedestal is sealed, without the necessity of temporarily stopping the purge process on the inner space of the chamber, the process of shifting the door part and opening the inner space of the storage container to the inner space of the chamber can be performed smoothly and properly. Thus, it becomes possible to provide a door opening and closing apparatus capable of preventing rising of particles, displacement of the transfer target object stored in the storage container on the placing pedestal, any failure of the door part and the lid part and the like associated with the opening process. Further, it becomes also possible to provide a transfer apparatus such as an EFEM including the door opening and closing apparatus, and a storage container opening method.

### BRIEF DESCRIPTION OF THE DRAWINGS

FIG. 1 is a side view schematically showing the relative positional relationship between an EFEM including a door opening and closing apparatus according to one embodiment of the present invention and its peripheral apparatuses;

FIG. 2 is a perspective view of the door opening and closing apparatus according to the embodiment from which components are partially omitted;

FIG. 3 is a view on arrow x in FIG. 2;

FIG. 4 is a view on arrow y in FIG. 2;

FIG. 5 is a schematic cross-sectional view of the door opening and closing apparatus according to the embodiment as seen from the side, in the state where a storage container on a placing pedestal is spaced apart from a frame and a door part is at a totally closed position;

FIG. 6 is a diagram showing the state where the storage container on the placing pedestal is closely attached to the frame and the door part is at the totally closed position, in a manner corresponding to FIG. 5;

FIG. 7 is a diagram showing the state where the door part is at a shifting direction switching position, in a manner corresponding to FIG. 5;

FIG. 8 is a diagram showing the state where the door part is at a totally open position, in a manner corresponding to FIG. 5;

FIG. 9 is a schematic cross-sectional view of the door opening and closing apparatus according to the embodiment as seen from above at a predetermined height position in the state where the storage container on the placing pedestal is closely attached to the frame and the door part is at the totally closed position;

FIG. 10 is a flowchart showing the operation procedure of the EFEM according to the present embodiment;

FIG. 11 is a flowchart showing the operation procedure of the EFEM according to the present embodiment;

FIG. 12 is a diagram showing a door opening and closing apparatus according to one variation of the embodiment, in a manner corresponding to FIG. 5;

FIG. 13 is a diagram showing a door opening and closing apparatus according to another variation of the embodiment, in a manner corresponding to FIG. 7;

FIG. 14 is a diagram showing the door opening and closing apparatus according to the variation, in a manner corresponding to FIG. 8; and

FIG. 15 is a diagram showing a door opening and closing apparatus according to still another variation of the embodiment, in a manner corresponding to FIG. 8.

### DETAILED DESCRIPTION OF PREFERRED EMBODIMENTS

In the following, with reference to the drawings, a description will be given of one embodiment of the present invention.

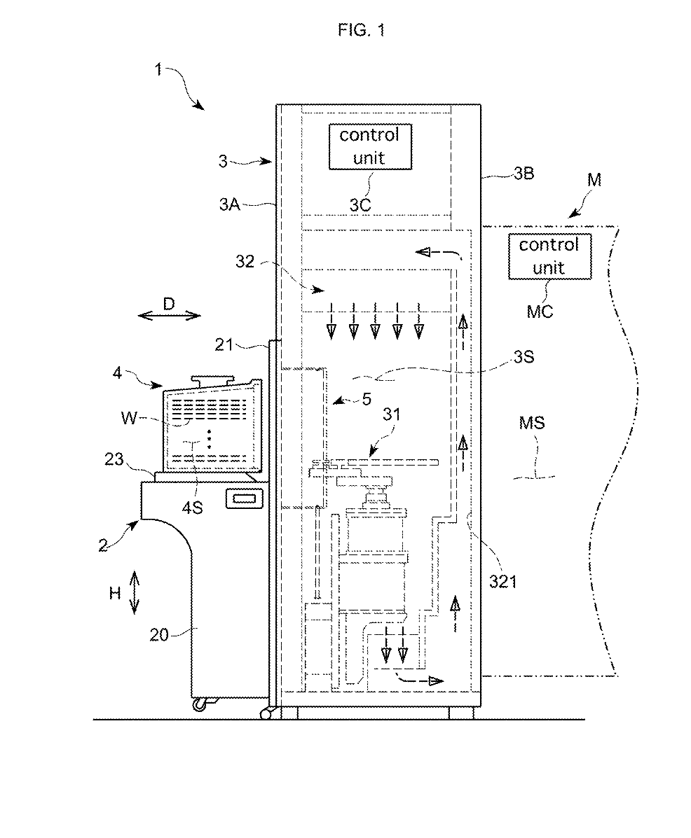

A door opening and closing apparatus 2 according to the present embodiment is used, for example, in a process of manufacturing semiconductors. As shown in FIG. 1, the door opening and closing apparatus 2 structures part of the wall surface of a transfer room 3 in a clean room, and puts in and takes out transfer target objects W to and from between the transfer room 3 and a storage container 4. In the following, a description will be given of a mode in which the door opening and closing apparatus 2 is a load port that structures part of an EFEM (Equipment Front End Module) 1 being one example of the transfer apparatus of the present invention, and the transfer target objects W, for example wafers, are transferred between the storage container 4 (e.g., a FOUP) and the transfer room 3 (a wafer transfer room). Note that, while the size of wafers handled with the EFEM is standardized as SEMI (Semiconductor Equipment and Materials International) standards, from the viewpoint of improving productivity, the diameter of wafers has been increased. It is promoted to switch the wafer size from the conventional 300 mm diameter (a 150 mm radius) to the size ranging from a 450 mm diameter (a 225 mm radius) to a 500 mm diameter (a 250 mm radius).

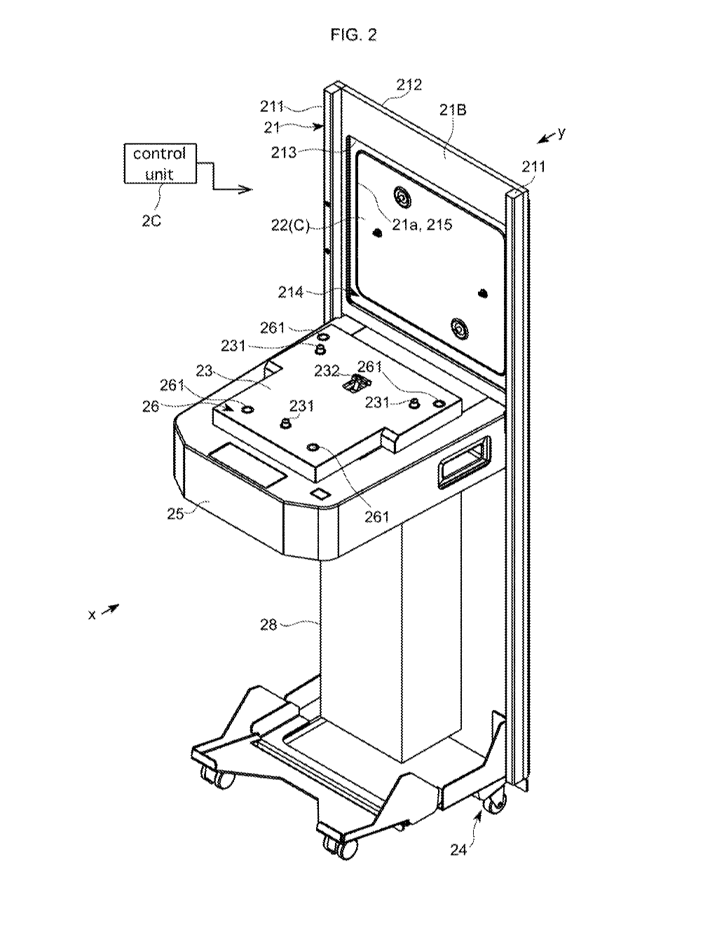

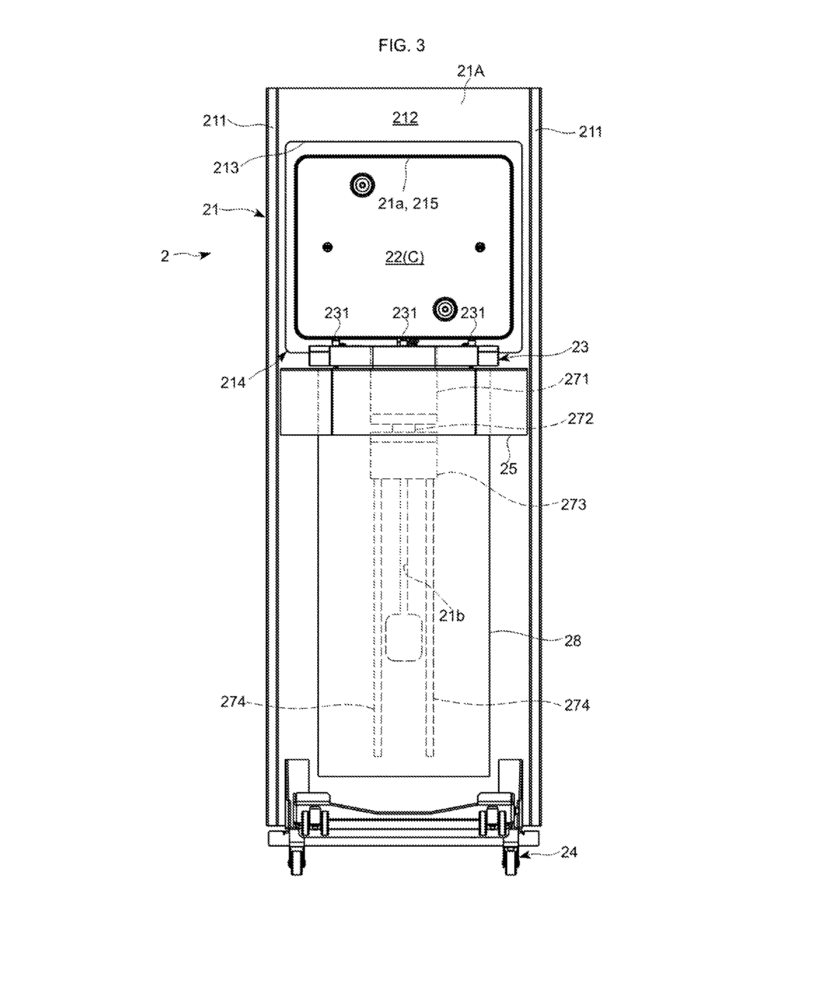

As shown in FIGS. 1 to 4, the door opening and closing apparatus 2 according to the present embodiment includes: a plate-shaped frame 21 that structures part of a wall surface 3A of the transfer room 3, and is provided with an opening 21a for opening an inner space 3S of the transfer room 3; a door part 22 opening and closing the opening 21a of the frame 21; and a placing pedestal 23 provided substantially horizontally to the frame 21. Further, FIGS. 2 and 3 show the state where an exterior cover 20 shown in FIG. 1 provided below the placing pedestal 23 is removed and the internal structure is partially exposed.

The frame 21 is disposed upright, and has an approximate quadrangular plate-shape. The frame 21 is provided with the opening 21a of the size communicable with a transfer opening 41 of the storage container 4 placed on the placing pedestal 23. The door opening and closing apparatus 2 according to the present embodiment can be used with the frame 21 closely attached to the transfer room 3. Further, below the frame 21, leg parts 24 having casters and installation legs are provided. In the present embodiment, the frame 21 includes support struts 211 stood on the opposite sides, a frame body 212 supported by the support struts 211, and a window unit 214 attached to a window part 213 opened to have an approximate quadrangular-shape at the frame body 212.

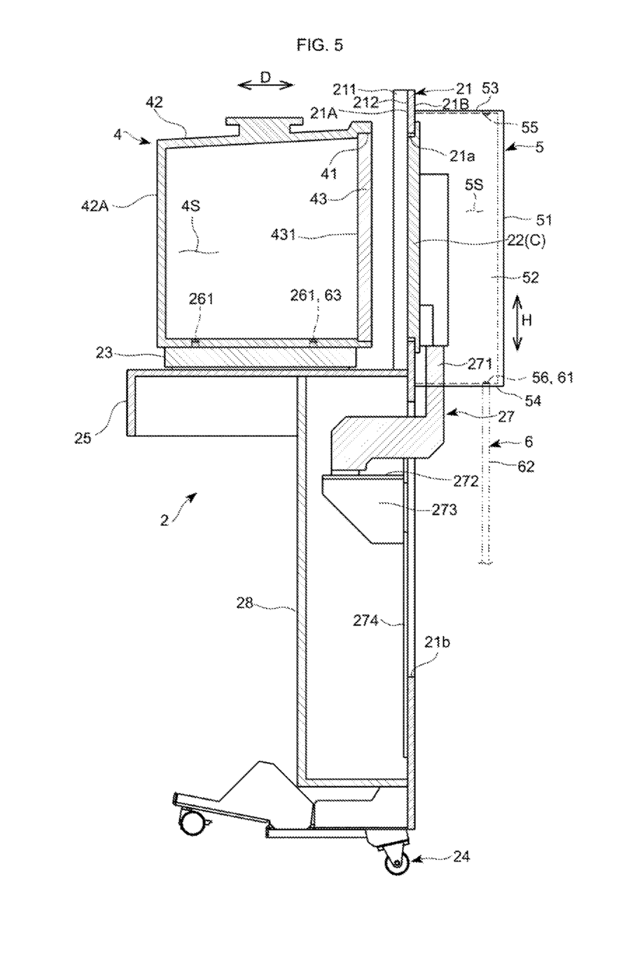

The window unit 214 is provided at the position opposing to a lid part 43 of the storage container 4. An opening 215 provided at the window unit 214 corresponds to the opening 21a formed at the frame 21 of the present invention. In FIG. 5 and subsequent drawings which will be referred to later, the window unit 214 is not shown. Instead, the frame 21 is schematically shown to have the frame body 212 provided with the opening 21a.

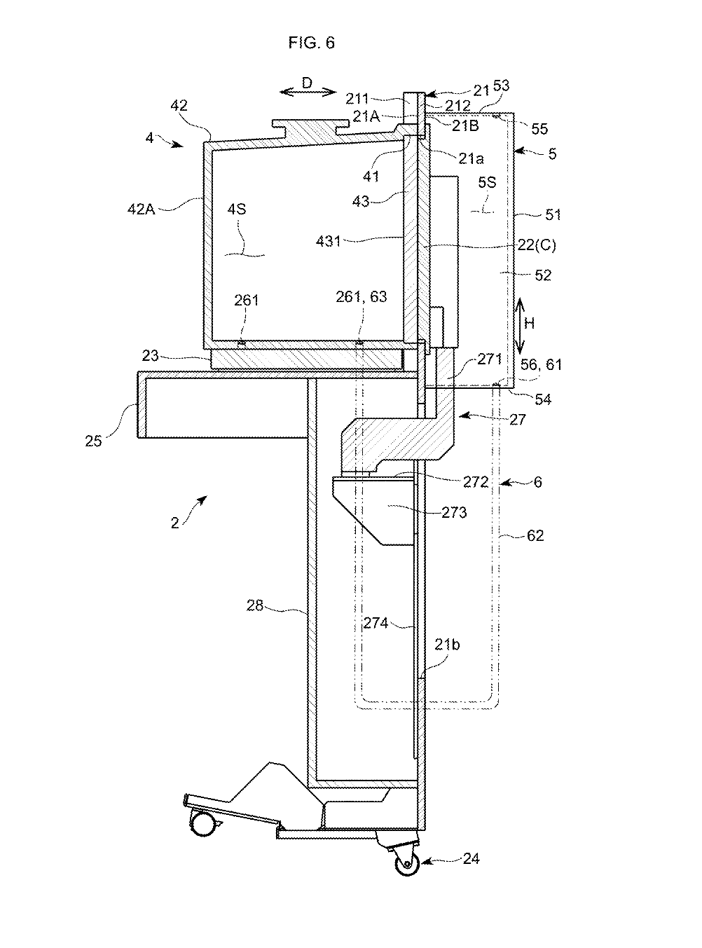

The placing pedestal 23 of the door opening and closing apparatus 2 is disposed at the upper portion of a horizontal pedestal 25 (a support pedestal) which is disposed substantially horizontally at the position slightly upper than the center in the height direction of the frame 21. On the placing pedestal 23, the storage container 4 can be placed such that the lid part 43 capable of opening and closing an inner space 4S of a storage container body 42 faces the door part 22. Further, as shown in FIGS. 5 and 6, the placing pedestal 23 is structured to be capable of approaching and retracting relative to the frame 21, between the position where the lid part 43 of the storage container 4 is closely attached to the door part 22 (see FIG. 6) and the position where the lid part 43 is spaced apart by a predetermined distance from the door part 22 (see FIG. 5). As shown in FIG. 2, the placing pedestal 23 has a plurality of projections 231 projecting upward. By allowing the projections 231 to engage with holes (not shown) formed at the bottom surface of the storage container 4, the storage container 4 is positioned on the placing pedestal 23. Note that, in FIGS. 5 and 6 and others, as the placement state of the storage container 4 on the placing pedestal 23, the state where the bottom surface of the storage container 4 is in contact with the upper surface of the placing pedestal 23 is shown. However, actually, the storage container 4 is supported by the plurality of positioning projections 231 projecting higher than the upper surface of the placing pedestal 23 engaging with the bottomed holes formed at the bottom surface of the storage container 4. Accordingly, the upper surface of the placing pedestal 23 and the bottom surface of the storage container 4 are not in contact with each other, and a predetermined clearance is formed between the upper surface of the placing pedestal 23 and the bottom surface of the storage container 4. Further, a lock claw 232 for fixing the storage container 4 to the placing pedestal 23 is provided. By attaining the locked state where the lock claw 232 is hooked and fixed to a lock receiving part (not shown) provided at the bottom surface of the storage container 4, in cooperation with the positioning projections 231, it becomes possible to guide the storage container 4 to a proper position on the placing pedestal 23 and fix the storage container 4 thereto. Further, by canceling the locked state of the lock claw 232 relative to the lock receiving part provided at the bottom surface of the storage container 4, the storage container 4 can be spaced apart from the placing pedestal 23.

In the present embodiment, in the front-rear direction D (see FIG. 1 and others) along which the storage container 4 placed on the placing pedestal 23 of the load port and the frame 21 are aligned with each other, the frame 21 side is defined to be the front side, and the storage container 4 side is defined to be the rear side.

The door opening and closing apparatus 2 according to the present embodiment is provided with a plurality of nozzles 261 at predetermined positions on the placing pedestal 23. The nozzles 261 are provided so as to structure a bottom purge part 26 that can injects the environmental gas (also referred to as the purge gas, and mainly nitrogen gas or dry air is employed), which is a gas appropriately selected from nitrogen gas, an inert gas, dry air and the like, from the bottom surface side of the storage container 4 into the storage container 4, thereby allowing replace the gas atmosphere in the storage container 4 by the environmental gas. However, with the door opening and closing apparatus 2 according to the present embodiment, the nozzles 261 previously provided on the placing pedestal 23 are used as nozzles that structure part of a pressure adjusting part 6 which will be described later. The plurality of nozzles 261 originally function as the bottom purge injection nozzle injecting the environmental gas into storage container 4, or the bottom purge discharge nozzle discharging the gas atmosphere in the storage container 4. The nozzles 261 may be provided, for example, in pairs at the positions spaced away in the width direction of the placing pedestal 23. Further, the plurality of nozzles 261 can be coupled to injection ports and discharge ports (both not shown) provided at the bottom part of the storage container 4, in the state being fitted therein. The nozzles 261 (the bottom purge injection nozzles, the bottom purge discharge nozzles) or the injection ports and the discharge ports have the valve function of preventing backflow of gas. The fitting portions between the nozzles 261 (the bottom purge injection nozzles, the bottom purge discharge nozzles) and the injection ports and the discharge ports of the storage container 4 are sealed by gaskets or the like provided at the nozzles 261. Note that, with the door opening and closing apparatus 2 according to the present embodiment, when the storage container 4 is not placed on the placing pedestal 23, the nozzles 261 (the bottom purge injection nozzles, the bottom purge discharge nozzles) are positioned lower than the upper surface of the placing pedestal 23. Then, for example when it is detected that a pressed part of a pressure sensor provided at the placing pedestal 23 is pressed by the bottom surface part of the storage container 4, the nozzles 261 (bottom purge injection nozzles, bottom purge discharge nozzles) are progressed upward by a signal from a control unit 2C, to couple to the injection ports and the discharge ports of the storage container 4.

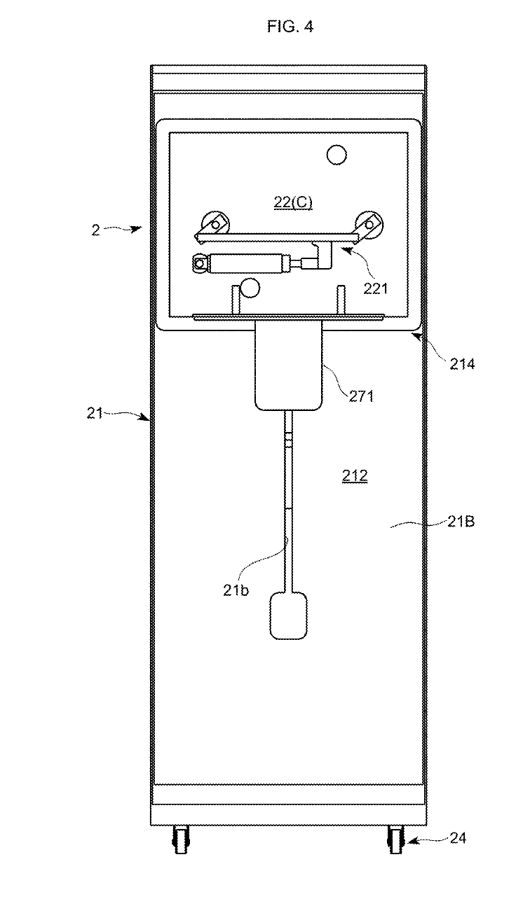

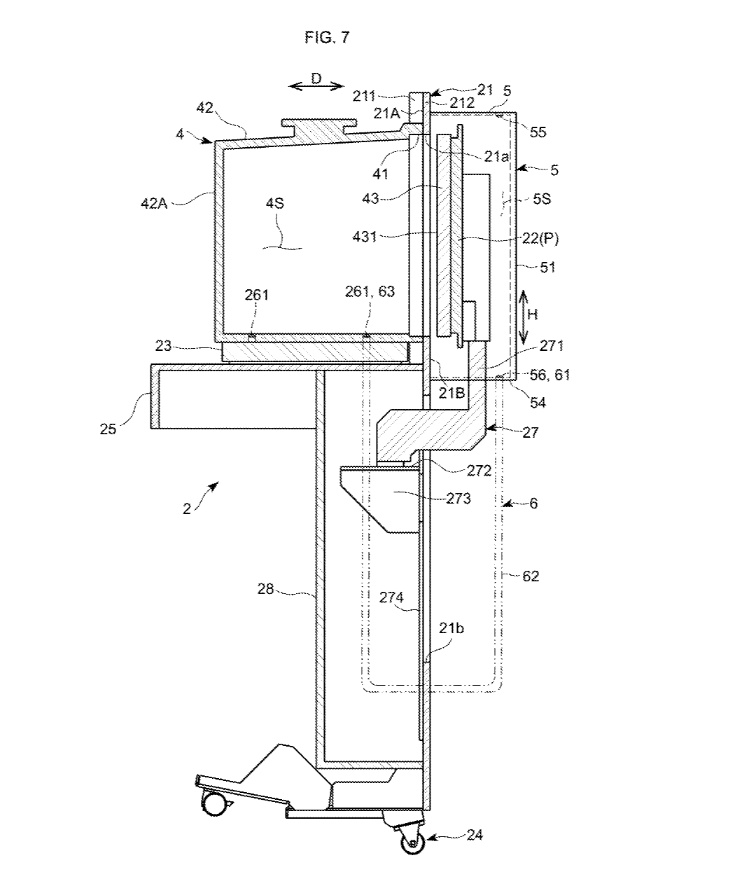

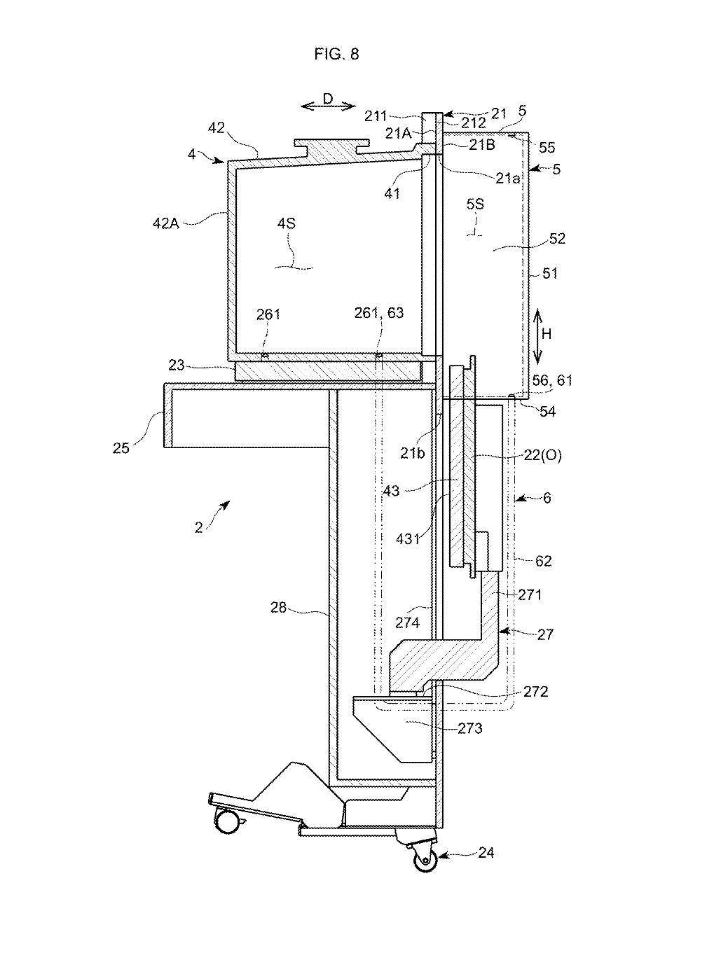

The door part 22 includes a coupling mechanism 221 (see FIG. 4) that is capable of switching between the lid coupled state in which the door part 22 is coupled to the lid part 43 of the storage container 4 and the lid part 43 can be removed from the storage container body 42, and the lid coupling released state in which the coupling state with the lid part 43 is released and the lid part 43 is attached to the storage container body 42. The door part 22 is capable of shifting along a predetermined shifting route while integrally holding the lid part 43 by the coupling mechanism 221. As shown in FIGS. 5 to 8, the door opening and closing apparatus 2 according to the present embodiment can shift between a totally closed position (C) in which the door part 22 seals, by the lid part 43 held by the door part 22, the inner space 4S of the storage container body 42, and a totally open position (O) in which the lid part 43 held by the door part 22 is spaced apart from the storage container body 42 to fully open the inner space 4S forward and to the transfer room 3 of the storage container body 42. In the present embodiment, the attitude of the door part 22 positioned at the totally open position (O) shown in FIG. 8 is set to the same upright attitude of the door part 22 positioned at the totally closed position (C) shown in FIGS. 5 and 6. Also, the upright attitude is maintained while shifting between the totally open position (O) and the totally closed position (C). That is, the shifting route of the door part 22 between the totally open position (O) and the totally closed position (C) is formed by a route through which the door part 22 in the totally closed position (C) is shifted to the transfer room 3 while maintaining its height position (the horizontal route), and a route through which the door part 22 in the totally open position (O) is shifted upward while maintaining its front-rear position (the vertical route). At the point where the horizontal route and the vertical route cross each other, the shifting direction of the door part 22 is switched from the horizontal direction to the vertical direction, or from the vertical direction to the horizontal direction. At the point where the horizontal route and the vertical route cross each other, the door part 22 is positioned at a shifting direction switching position (P) shown in FIG. 7. As can be seen from FIG. 7, in order to allow the door part 22 positioned at the shifting direction switching position (P) to shift in either the vertical direction or the horizontal direction, the lid part 43 of the storage container 4 held by the door part 22 positioned at the shifting direction switching position (P) is positioned, together with the door part 22, at the forward position than the frame 21 (the position where the lid part 43 is fully spaced apart from the storage container body 42 and disposed in the inner space 3S of the transfer room 3). In particular, as will be described later, the door opening and closing apparatus 2 according to the present embodiment includes a chamber 5. Therefore, it is structured such that at least the shifting between the totally closed position (C) and the shifting direction switching position (P) of the door part 22 is carried out in an inner space 5S of the chamber 5. Further, it is structured such that the door part 22 shifting between the totally closed position (C) and the totally open position (O) via the shifting direction switching position (P) does not interfere with the chamber 5.

Such shifting of the door part 22 is realized by a door shifting mechanism 27 provided at the door opening and closing apparatus 2. As shown in FIGS. 5 to 8, the door shifting mechanism 27 includes a support frame 271 supporting the door part 22, a movable block 273 that supports the support frame 271 via a slide support part 272 so as to be shiftable in the front-rear direction D, a slide rail 274 that supports the movable block 273 so as to be shiftable in the top-bottom direction H, and a drive source (e.g., a not-shown actuator) for causing the door part 22 to shift in the front-rear direction D along the horizontal route, and in the top-bottom direction H along the vertical route. By providing a drive instruction from the control unit 2C to this actuator, the door part 22 is caused to shift in the front-rear direction D and the top-bottom direction H. Note that, an actuator for the forward-back shift and an actuator for the up-down shift may be separately provided, or the forward-back shift and the up-down shift may be performed using a common actuator as the drive source.

The support frame 271 supports the rear lower portion of the door part 22. The support frame 271 has an approximate crank-shape which extends downward, passes through a slit-like insert hole 21b provided at the frame 21, and stretches to the outside of the transfer room 3 (on the placing pedestal 23 side). The slide support part 272 for supporting the support frame 271, the movable block 273, and the slide rail 274 are also disposed on the placing pedestal 23 side than the frame 21, that is, outside the transfer room 3. The slide support part 272, the movable block 273, and the slide rail 274 become sliding portions when the door part 22 is shifted. In the present embodiment, by virtue of disposing the foregoing components outside the transfer room 3 and designing the insert hole 21b to be small slit-like, even in the case where particles are present while the door part 22 is shifting, entry of particles into the transfer room 3 can be prevented or suppressed. Further, a cover 28 is provided to cover components or portions of the door shifting mechanism 27 disposed outside the transfer room 3, specifically, part of the support frame 271, the slide support part 272, the movable block 273, and the slide rail 274. Thus, it is designed such that environmental gas in the transfer room 3 does not leak outside the EFEM 1 via the insert hole 21b formed at the frame 21.

Further, as shown in FIG. 1 and FIGS. 5 to 8, the door opening and closing apparatus 2 according to the present embodiment includes the chamber 5 provided on the transfer room 3 side than the opening 21a of the frame 21. The chamber 5 is capable of blocking the storage container 4, whose inner space is opened by the door part 22, from the front side of the storage container 4. Note that, in FIG. 1, the entire chamber 5 is represented by a shade line (a broken line). In FIGS. 5 to 8 showing the side cross section of the door opening and closing apparatus 2, the chamber 5 is not shown by the cross-sectional view but schematically shown as a side view. Further, in FIGS. 2 to 4, the chamber 5 is not shown.

The chamber 5 is provided at the position opposing to the transfer opening 41 of the storage container 4 and the opening 21a of the frame 21. Then, in the present embodiment, when the door part 22 is shifted to the totally open position (O) and thus the sealed state of the storage container 4 by the lid part 43 is released and the inner space 4S of the storage container 4 is opened forward, the space with which the inner space 4S of the storage container 4 communicates is blocked by the chamber 5 at least in the front-rear direction. That is, the space with which the inner space 4S of the storage container 4 communicates can be limited to the inner space 5S of the chamber 5. The chamber 5 has an upright wall 51 slightly greater than the opening dimension of the opening 21a formed at the frame 21, a right and left pair of sidewalls 52 extending from the opposite edges of the upright wall 51 toward the frame 21, and an upper wall 53 and a bottom wall 54 respectively extending from the upper edge and the lower edge of the upright wall 51 toward the frame 21, each being integrated with or substantially integrated with the chamber 5. Then, when the door part 22 is positioned at the totally closed position (C), the inner space 5S of the chamber 5 becomes a space sealed or substantially sealed by the walls 51, 52, 53, and 54 of the chamber 5, the frame 21 and the door part 22. Further, when the door part 22 is shifted to the totally open position (O), the inner space 5S of the chamber 5 becomes a sealed or substantially sealed space which communicates with the inner space 4S of the storage container 4 via the transfer opening 41 and the opening 21a of the frame 21.

With the door opening and closing apparatus 2 according to the present embodiment, the chamber 5 is structured to be capable of shifting by a not-shown chamber shifting mechanism, between the blocking position where the chamber 5 covers the opening 21a of the frame 21 from the transfer room 3 side (see FIGS. 5 to 8), and the chamber retract position (not shown) where the chamber 5 can open the inner space 4S of the storage container 4 connecting to the opening 21a to the inner space 3S of the transfer room 3, and consequently to an inner space MS of the processing apparatus M. An exemplary chamber shifting mechanism may include an air cylinder for horizontally shifting the chamber 5, a guide rail part for guiding the horizontal movement of the chamber 5, an air cylinder for raising and lowering the chamber 5, and a guide rail part for guiding the up-down movement of the chamber 5. The door opening and closing apparatus 2 of the present embodiment is set to be capable of shifting the door part 22 and the chamber 5 independently of each other. Further, the bottom wall 54 of the chamber 5 is provided with an opening or a slit through which the members or the mechanism can pass (not shown). Thus, in the state where the chamber 5 is set at the blocking position and when the door part 22 is shifted, interference between the door part 22 or the door shifting mechanism 27 and the chamber 5 can be avoided.

Then, the door opening and closing apparatus 2 according to the present embodiment employs the chamber 5 including a gas supply nozzle 55 that supplies an environmental gas such as nitrogen gas into the chamber 5, and a gas discharge nozzle 56 that discharges the environmental gas in the chamber 5 to the outside of the chamber 5. This makes it possible to perform the chamber purge process in which an environmental gas is supplied into the chamber 5 from the gas supply nozzle 55 provided at the upper wall 53 of the chamber 5. When the chamber purge process is performed, the gas atmosphere in the chamber 5 is discharged from the gas discharge nozzle 56 provided at the bottom wall 54 of the chamber 5. That is, the door opening and closing apparatus 2 of the present embodiment is structured to discharge the air or an environmental gas of low cleanliness with which the inner space 5S of the chamber 5 is filled, to the outside of the chamber 5 via the gas discharge nozzle 56. Thus, the chamber 5 can be filled with the environmental gas supplied from the gas supply nozzle 55 at a high concentration. Note that, the gas supply nozzle 55 and the gas discharge nozzle 56 have a valve function of regulating the backflow of gas.

Further, the door opening and closing apparatus 2 according to the present embodiment includes the pressure adjusting part 6 that allows the inner space 5S of the chamber 5 and the inner space 4S of the storage container 4 to communicate with each other using a route other than the opening 21a formed at the frame 21.

The pressure adjusting part 6 according to the present embodiment includes a gas discharge part 61 that discharges an environmental gas supplied to the inner space 5S of the chamber 5 to the outside of the chamber 5, a gas introduction part 63 that introduces the environmental gas to the inner space 4S of the storage container 4, and a gas discharge route 62 disposed between the gas discharge part 61 and the gas introduction part 63. The upstream end of the gas discharge route 62 is coupled to the gas discharge part 61. The downstream end of the gas discharge route 62 is coupled to the gas introduction part 63. Via such a gas discharge route 62, the environmental gas discharged from the chamber 5 can be introduced into the storage container 4. In the present embodiment, the gas discharge part 61 is structured by the gas discharge nozzle 56 provided at the bottom wall 54 of the chamber 5. Further, the gas introduction part 63 is formed by the bottom purge injection nozzle out of the nozzles 261 provided at the placing pedestal 23. Here, FIGS. 5 to 8 show the manner in which among a plurality of nozzles 261 provided at the positions spaced apart in the front-rear direction D on the placing pedestal 23, the nozzle 261 relatively on the frame 21 side is caused to function as the gas introduction part 63. Further, the pressure adjusting part 6 according to the present embodiment structures the gas discharge route 62 by a discharge tube whose upstream end is coupled to the gas discharge nozzle 56. Then, the downstream end of the discharge tube 62 is coupled to the nozzle 261 functioning as the gas introduction part 63.

As schematically shown in FIGS. 6 to 8, in the discharge tube 62 structuring the pressure adjusting part 6, predetermined portions between the upstream end and the downstream end penetrate the frame 21 in the thickness direction (the front-rear direction) and penetrate the horizontal pedestal 25 and the placing pedestal 23 in the height direction. Note that, the portions of the frame 21, the horizontal pedestal 25, and the placing pedestal 23 where the discharge tube 62 penetrates are appropriately sealed. Thus, a reduction in the sealing performance attributed to the clearances of the penetrated portions can be prevented or suppressed. Further, the present embodiment employs the discharge tube 62 that exhibits excellent flexibility or stretchiness (including the accordion type) being capable of following the shifting of the chamber 5 or the placing pedestal 23. In the discharge tube 62, the portions fitted in the gas discharge nozzle 56 and the nozzle 261 functioning as the gas introduction part 63 are sealed by gaskets or the like.

The door opening and closing apparatus 2 structured as described above executes a predetermined operation by the control unit 2C issuing drive instructions to the constituent members. The EFEM 1 according to the present embodiment includes a plurality of (e.g., three) door opening and closing apparatuses 2 disposed along one wall surface 3A of the transfer room 3. As described above, in the present embodiment, in the front-rear direction D along which the storage container 4 and the frame 21 are aligned with each other, the frame 21 side is defined to be the front side, and the storage container 4 side is defined to be the rear side. Here, in the transfer room 3, the wall surface 3A where the door opening and closing apparatuses 2 are disposed can be regarded as the back surface.

As shown in FIG. 1, the EFEM 1 mainly includes the door opening and closing apparatuses 2 (the load ports) and the transfer room 3 which are provided adjacent to each other in a common clean room. For example, the processing apparatus M (a semiconductor processing apparatus) is provided adjacent to a wall surface 3B, which faces the wall surface 3A (the back surface) where the door opening and closing apparatuses 2 are disposed, of the transfer room 3. In the clean room, the inner space MS of the processing apparatus M, the inner space 3S of the transfer room 3, and the inner space 4S of the storage container 4 placed on each of the door opening and closing apparatuses 2 are maintained at a high cleanliness level. On the other hand, the space where the door opening and closing apparatuses 2 are disposed, in other words, the outside of the processing apparatus M and the outside of the EFEM 1 are at a relatively low cleanliness level. Note that, FIG. 1 is a side view schematically showing the relative positional relationship between the door opening and closing apparatus(es) 2 and the transfer room 3, and the relative positional relationship between the EFEM 1 including the door opening and closing apparatus(es) 2 and the transfer room 3 and the processing apparatus M.

The processing apparatus M includes a load lock room disposed at the position relatively near to the transfer room 3, and a processing apparatus body disposed at the position relatively far from the transfer room 3. In the present embodiment, as shown in FIG. 1, in the front-rear direction D of the EFEM 1, the door opening and closing apparatus(es) 2, the transfer room 3, and the processing apparatus M are disposed in this order and in intimate contact with each other.

In the transfer room 3, a transfer robot 31 that is capable of transferring wafers W being the transfer target objects W between the storage container 4 and the processing apparatus M is provided in the inner space 3S. The transfer robot 31 includes an arm made up of a plurality of linkage elements coupled to each other so as to be turnable horizontally and having a hand on its tip portion, and a running part that turnably supports an arm base structuring the proximal end of the arm and runs in the width direction of the transfer room 3 (the juxtaposed direction of the door opening and closing apparatuses 2). The transfer robot 31 has a linkage structure (a multijoint structure) in which the shape thereof changes between the folded state where the arm length is minimized and the stretched state where the arm length is longer than in the folded state. Note that, it is also possible to structure an EFEM in which one of or both of a buffer station and an aligner are disposed on the side surface of the transfer room 3.

In connection with the transfer room 3, by the door opening and closing apparatuses 2 and the processing apparatus M being connected, the inner space 3S is substantially sealed. Inside the transfer room 3, by performing the purge process with an environmental gas using not-shown gas supply port and gas discharge port, the concentration of the environmental gas can be increased. Then, a fan filter unit 32 is provided at the upper portion of the wafer transfer room 3 to send the gas downward, and the gas is suctioned by a chemical filter provided at the lower portion. The suctioned gas is returned to the upper fan filter unit 32 via a circulation duct 321. Thus, downflow being an air flow flowing from an upper point to a lower point in the inner space 3S of the transfer room 3 can be formed. Accordingly, cleanliness can be maintained by circulating the gas inside the transfer room 3. Further, even in the case where particles which may contaminate the surface of the wafers W exist in the inner space 3S of the transfer room 3, the particles are pushed downward by the downflow, and the particles can be suppressed from attaching to the surface of wafers W while being transferred. FIG. 1 schematically shows the gas flow by the fan filter unit 32 as being represented by arrows.

In the present embodiment in which the chamber 5 is disposed in the inner space 3S of the transfer room 3 where the concentration of the environmental gas is high, control is exerted such that the purge process with the environmental gas on the inner space 5S of the chamber 5 (chamber purge process) can be performed simultaneously with or separately from the purge process with the environmental gas on the inner space 3S of the transfer room 3. That is, the gas supply nozzle 55 provided at the upper wall 53 of the chamber 5 may supply, into the chamber 5, an environmental gas supplied from a gas supply source dedicated to the chamber purge process. Alternatively, the gas supply nozzle 55 may supply an environmental gas supplied into the transfer room 3 into the chamber 5 as it is.

In the present embodiment, the FOUP is employed as the storage container 4. The storage container 4 according to the present embodiment includes a storage container body 42 which is capable of opening the inner space 4S only forwardly via the transfer opening 41 formed at the front surface (the surface on the frame 21 side), and the lid part 43 capable of opening and closing the transfer opening 41. The storage container 4 is of a known structure, in which a plurality of wafers W being the transfer target objects W are stored in a multistage manner in the top-bottom direction H, and the wafers W can be put in or taken out via the transfer opening 41.

The storage container body 42 integrally has a back wall, a right and left pair of sidewalls, an upper wall, and a bottom wall. In the inner space 4S surrounded by the walls, a shelf part 421 (a wafer placing part) in which the transfer target objects W can be placed by a plurality of stages and at a predetermined pitch is provided. The boundary portion between each of the walls structuring the storage container body 42 forms a mild curved shape. Further, at the center of the upper surface of the upper wall, a flange part gripped by a storage container transfer apparatus (e.g., an OHT: Over Head Transport) is provided.

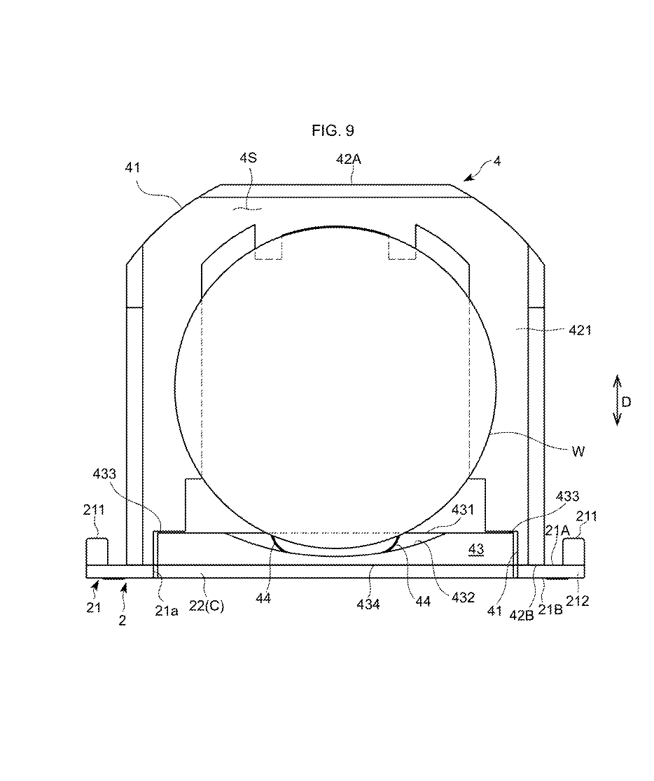

The lid part 43 faces the door part 22 of the door opening and closing apparatus 2 when the storage container 4 is placed on the placing pedestal 23 of the door opening and closing apparatus 2. The lid part 43 has an approximate plate-like shape. The height dimension of the lid part 43 is set to be substantially equal to the height dimension of the surface, which can be closely attached to the lid part 43, of the door part 22. Note that, FIG. 5 and others schematically show the lid part 43 set to have a height dimension slightly greater than the height dimension of the surface, which can be closely attached to the lid part 43, of the door part 22. The lid part 43 is provided with a latch part (not shown) with which the lid part 43 can be locked to the storage container body 42. Further, as shown in FIG. 9, a retainer 44 is provided at the inner surface 431 of the lid part 43. The retainer 44 may be integrally or substantially integrally provided at the lid part 43. On the other hand, when the retainer 44 is removably attached to the lid part 43, just replacement of the retainer 44 can address any damage to the retainer 44. Further, the number of the retainer holding one wafer may be one or two or more, and the shape of the retainer 44 itself can be changed as appropriate. Such a retainer 44 that functions as a wafer retainer by holding the wafers W stored in the storage container 4 while elastically deforming from the inner surface 431 side of the lid part 43 is provided at the inner surface 431 of the lid part 43 (specifically, at a recess part 432 formed at the inner surface 431). Thus, it becomes possible to determine the position where the transfer target objects W are stored in the storage container 4, and to prevent any damage that may occur to the transfer target objects W being thin and fragile wafers or the like. Note that, gaskets 433 are provided at the predetermined portions, which are brought into contact with or brought near to the storage container body 42, of the inner surface 431 in the state where the transfer opening 41 is closed by lid part 43 (in the example shown in FIG. 9, at the opposite sides of the inner surface 431). Then, by bringing the gaskets 433 into contact with the storage container body 42 taking precedence over the inner surface 431 of the lid part 43 and allowing the gaskets 433 to elastically deform, the inner space 4S of the storage container 4 can be totally sealed. Note that, the chamber 5 is not shown in FIG. 9.

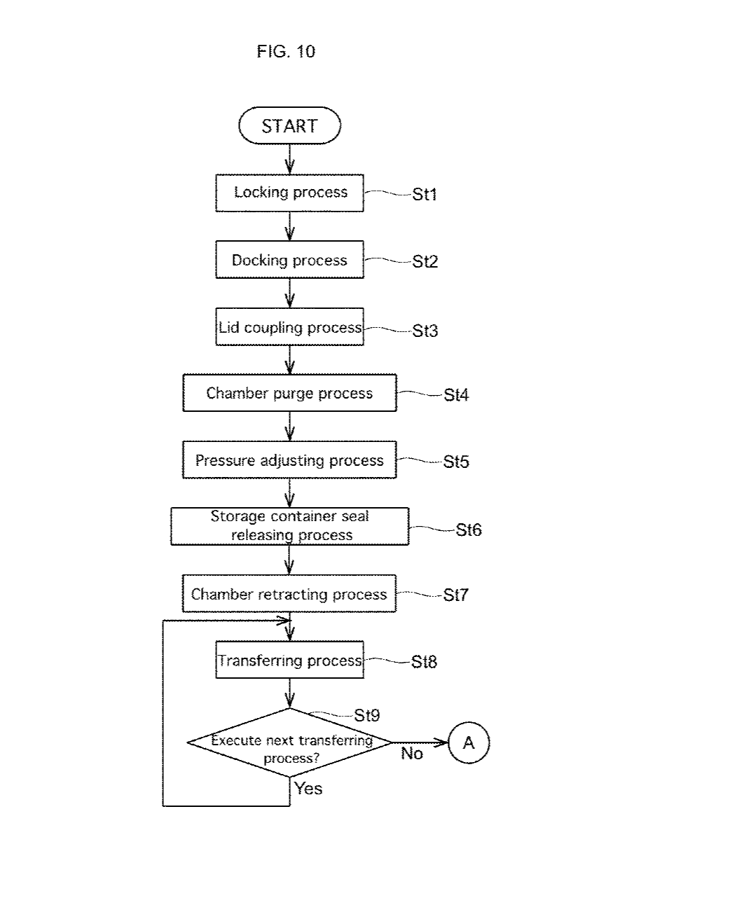

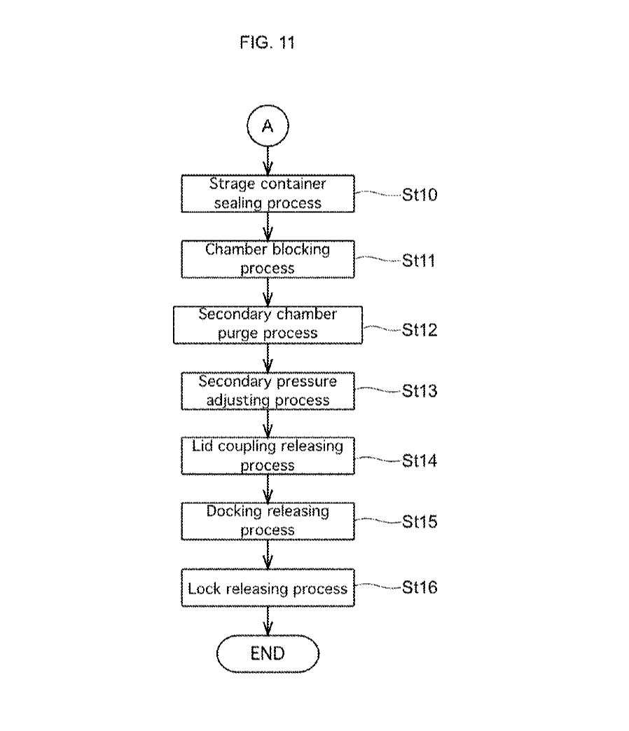

The door opening and closing apparatus 2 according to the present embodiment executes a predetermined operation by the control unit 2C issuing drive instructions to the constituent members. Note that, in the present embodiment, it is structured such that the control unit 2C included in the door opening and closing apparatus 2 issues drive instructions to the constituent members. The control unit 2C includes a memory unit, ROM, RAM, an I/O port, a CPU, an input/output interface (IF) that exchanges data with an external display apparatus (not shown) and the like, and buses connecting the foregoing components to each other to transmit information. The memory unit stores a control procedure corresponding to the type of the process executed in the door opening and closing apparatus 2. That is, the memory unit stores a predetermined operation program for each constituent member of the apparatus. Thus, the program according to the present embodiment is stored as a program capable of being executed by a non-transitory computer readable recording medium (a hard disk or the like). The ROM is structured by a hard disk, EEPROM, flash memory or the like, and is a recording medium storing an operation program of the CPU or the like. The RAM functions as the work area of the CPU and the like. The I/O port outputs, for example, control signals output from the CPU to the constituent members of the apparatus, and supplies information from sensors to the CPU. The CPU structures the center of the control unit 2C, and executes the operation program stored in the ROM. The CPU controls the operation of the door opening and closing apparatus in accordance with the program stored in the memory unit. The content of the program stored in the memory unit will be described together with the usage and operation of the EFEM 1 including the door opening and closing apparatus 2, with reference to FIGS. 10 and 11 and others showing the operation flow of the EFEM 1.

Firstly, by a storage container transfer apparatus such as an OHT that operates on a linear transfer line (a traffic line) extending along the common wall surface 3A, along which the door opening and closing apparatuses 2 are disposed, of the transfer room 3, the storage container 4 is transferred to the point above each door opening and closing apparatus 2, and placed on the placing pedestal 23. At this time, for example the positioning projections 231 provided at the placing pedestal 23 fit in the positioning recess parts of the storage container 4. Further, the control unit 2C causes the lock claw 232 on the placing pedestal 23 to enter the locked state (a locking process St1). Specifically, by hooking, on the lock receiving part (not shown) provided at the bottom surface of the storage container 4, the lock claw 232 on the placing pedestal 23 and fixing thereto, the locked state is entered. Thus, the storage container 4 can be placed at a predetermined normal position on the placing pedestal 23 and fixed thereto. In the present embodiment, the storage container 4 can be placed on the placing pedestal 23 of each of the door opening and closing apparatuses 2 disposed by three in number so as to be juxtaposed to each other in the width direction of the transfer room 3. Further, it is also possible to structure such that a seat sensor (not shown) that detects whether or not the storage container 4 is placed on the placing pedestal 23 at a predetermined position detects that the storage container 4 is placed at a normal position on the placing pedestal 23.

Next, in each door opening and closing apparatus 2 according to the present embodiment, the control unit 2C causes the placing pedestal 23 to advance toward the frame 21 from the position shown in FIG. 5 to the position shown in FIG. 6. Thus, the front surface of the storage container 4 (a front surface 42B of the storage container body 42 and an outer surface 434 of the lid part 43 being flush with each other) is brought into contact with a frame rearmost surface 21A, which is at the circumference of the opening 21a and situated nearest to the storage container body 42, of the frame 21 (a docking process St2). Note that, the surface denoted by 21B in FIG. 5 and others is the frame foremost surface, which is at the circumference of the opening 21a and situated farthest from the storage container body 42, of the frame 21. Subsequently, in each door opening and closing apparatus 2 according to the present embodiment, the control unit 2C switches the coupling mechanism 221 to the lid coupled state (a lid coupling process St3). This process allow the door part 22, which is previously on standby at the totally closed position (C), to couple to the lid part 43 with the coupling mechanism 221 and to hold in the closely attached state. Further, the state where the lid part 43 is removable from the storage container body 42 is entered. Further, in each door opening and closing apparatus 2 according to the present embodiment, at the time point where the storage container 4 is placed at the normal position on the placing pedestal 23, the control unit 2C detects that the bottom surface part of the storage container 4 has pressed the pressed part of for example, a pressure sensor provided at the placing pedestal 23. This triggers the control unit 2C to issue a drive instruction (signal) of advancing the nozzles 261 provided at the placing pedestal 23 (all the nozzles 261 including the nozzles functioning as the gas introduction part 63) to be higher than the upper surface of the placing pedestal 23. As a result, the nozzles 261 are coupled to the injection ports and the discharge ports of the storage container 4, and the state where the purge process on the inside of the storage container 4 can be executed is entered.

Next, each door opening and closing apparatus 2 according to the present embodiment executes a chamber purge process St4 of supplying an environmental gas into the chamber 5. In the chamber purge process St4, an environmental gas supplied from any appropriate environmental gas supply source is injected into the chamber 5 from the gas supply nozzle 55 provided at the upper wall 53 of the chamber 5, to replace any gas in the chamber 5 by the environmental gas. By executing such a chamber purge process St4, the gas atmosphere in the chamber 5 is discharged from the gas discharge nozzle 56 (the gas discharge part 61) provided at the bottom wall 54 of the chamber 5. The discharged gas atmosphere (discharged gas) passes through the discharge tube 62, and is introduced into the inner space 4S of the storage container 4 from the nozzle 261 that functions as the gas introduction part 63 by being connected to the downstream end of the discharge tube 62, among the nozzles 261 provided at the placing pedestal 23. Thus, the inner space 4S of the storage container 4 is filled with the environmental gas with which the inner space 5S of the chamber 5 is filled, and the pressure of the inner space 4S of the storage container 4 becomes equal to the pressure of the inner space 5S of the chamber 5.

That is, in the present embodiment, the chamber purge process St4 is performed in the state where the inner space 4S of the storage container 4 is sealed. Then, a pressure adjusting process St5 of equalizing the pressure of the inner space 4S of the storage container 4 to the pressure of the inner space 5S of the chamber 5 (corresponding to the pressure adjusting step of the present invention) is executed, in which the environmental gas in the chamber 5 is introduced into the inner space 4S of the storage container 4 from the inner space 5S of the chamber 5 having undergone the chamber purge process St4 by the pressure adjusting part 6 using the route other than the opening 21a. During execution of the pressure adjusting process St5, the gas atmosphere in the storage container 4 is discharged from the nozzles 261 (the bottom purge discharge nozzles) coupled to the discharge ports formed at the storage container 4 and not connected to the discharge tube 62 of the pressure adjusting part 6, among the nozzles 261 provided at the placing pedestal 23. The discharged gas atmosphere (this gas atmosphere is air or an environmental gas of low cleanliness for a predetermined time period from the beginning of the execution of the pressure adjusting process, and after a lapse of the predetermined time period, it is the environmental gas with which the inner space 4S of the storage container 4 is filled) is discharged to any appropriate space not communicating with the storage container 4 and the transfer room 3, via any appropriate discharge route (not shown). Thus, the storage container 4 can be filled with the environmental gas at a high concentration, which is supplied from the nozzle 261 functioning as the gas introduction part 63. By executing such a pressure adjusting process St5, the inner space 4S of the storage container 4 is filled with the environmental gas, and the moisture concentration and the oxygen concentration in the storage container 4 are respectively reduced to predetermined values or lower than that. Thus, the ambient environment of the transfer target objects W in the storage container 4 is set to a low-moisture environment and a low-oxygen environment. Accordingly, the pressure adjusting process St5 can also be regarded as the process of replacing the gas atmosphere of the inner space 4S of the storage container 4 by the environmental gas (the storage container purging process).

Then, in each door opening and closing apparatus 2 according to the present embodiment, subsequently to the pressure adjusting process St5, the control unit 2C executes the process of shifting the lid part 43 together with the door part 22 and opening the opening 21a of the frame 21 and the transfer opening 41 of the storage container 4, thereby releasing the sealed state of the storage container 4 (a storage container seal releasing process St6). Specifically, as shown in FIGS. 7 and 8, the control unit 2C causes the door shifting mechanism 27 to shift the door part 22 in the inner space 5S of the chamber 5 from the totally closed position (C) toward the transfer room 3 along the horizontal route by a predetermined distance. Further, as shown in FIGS. 7 and 8, the control unit 2C causes the door part 22 arriving at the shifting direction switching position (P) to lower by a predetermined distance along the vertical route to be positioned at the totally open position (O). At the time point where the storage container seal releasing process St6 is executed, since the pressure difference between the inner space 5S of the chamber 5 and the inner space 4S of the storage container 4 is eliminated by the pressure adjusting process St5, the process of shifting the door part 22 toward the inner space 5S of the chamber 5 can be performed smoothly and properly. Note that, since the storage container seal releasing process St6 is the process of opening the storage container 4, it can also be referred to as “the storage container opening process”.

Subsequently, in each door opening and closing apparatus 2 according to the present embodiment, the control unit 2C executes the process of shifting the chamber 5 from the blocking position to the chamber retract position (not shown) where the inner space 4S of the storage container 4 leading to the opening 21a can be opened to the inner space 3S of the transfer room 3, and eventually to the inner space MS of the processing apparatus M (a chamber retracting process St7). Thus, the inner space 4S of the storage container body 42 and the inner space 3S of the transfer room 3 communicate with each other without being blocked by the chamber 5. Note that, it is also possible to employ the process procedure of: after execution of the chamber purge process St4, shifting the door part 22 from the totally closed position (C) to the shifting direction switching position (P); causing the door part 22 to enter the temporary standby state at this position, and shifting the chamber 5 from the blocking position to the chamber retract position in this state; and thereafter, shifting the door part 22 from the shifting direction switching position (P) to the totally open position (O). Further, in the present embodiment, at any appropriate time point where the pressure adjusting process St5 has completed, for example before the chamber retracting process St7 is executed, by stopping the supply of the environmental gas to the inner space 5S of the chamber 5, the gas use amount and the gas use time can be restricted, and a reduction in costs can be attained.

Then, in the state where the inner space 4S of the storage container body 42 and the inner space 3S of the transfer room 3 communicate with each other, the transfer robot 31 provided in the inner space 3S of the transfer room 3 executes access to the storage container 4, and carries out a transferring process on the transfer target objects W (a transferring process St8). The details of the transferring process that can be performed in the transferring process St8 are a process of the transfer robot 31 taking out the transfer target objects W in the storage container 4 with the hand, and a process of the transfer robot 31 putting in the transfer target objects W having undergone any appropriate process by the processing apparatus M into the storage container 4 with the hand. For example, when the transfer target objects W in the storage container 4 are transferred into the transfer room 3 by the transferring process St8, the transfer target objects W transferred into the transfer room 3 are transferred to the processing apparatus M (specifically, the load lock room) or to the buffer station or the aligner by the transfer robot 31. Further, the transfer target objects W having undergone any appropriate process by the processing apparatus M are directly stored in the inner space 4S of the storage container 4 from the inner space MS of the processing apparatus M by the transfer robot 31, or successively stored in the inner space 4S of the storage container 4 via the buffer station.

Then, in each door opening and closing apparatus 2 according to the present embodiment, when the transfer robot 31 executes next access to the storage container 4, (St9: Yes in FIG. 10), the transferring process St6 is repeatedly performed. In each door opening and closing apparatus 2 according to the present embodiment, when all the transfer target objects W in the storage container 4 have undergone the process by the processing apparatus M, the control unit 2C executes the process which is performed when the next transferring process is not executed (St9: No in FIG. 10). That is, the control unit 2C executes the process of causing the door shifting mechanism 27 to shift the door part 22 to the totally closed position (C); thereby closing the opening 21a of the frame 21 and the transfer opening 41 of the storage container 4; and thereby sealing the inner space 4S of the storage container 4 (a storage container sealing process St10, see FIG. 11). Specifically, as shown in FIGS. 7 and 8, the control unit 2C causes the door part 22 to rise by a predetermined distance along the vertical route, to shift from the totally open position (O) to the shifting direction switching position (P). Subsequently, the control unit 2C shifts the door part 22 arriving at the shifting direction switching position (P) in the direction to be away from the transfer room 3 (rearward) by a predetermined distance along the horizontal route. As a result, the opening 21a of the frame 21 and the transfer opening 41 of the storage container 4 are closed, whereby the inner space 4S of the storage container 4 is sealed. In accordance with the storage container sealing process St10, the retainer 44 provided at the inner surface 431 of the lid part 43 can hold the edge of the transfer target objects W while elastically deforming, and position all the transfer target objects W stored in the storage container 4 at the normal storage position (see FIG. 9).

Next, in each door opening and closing apparatus 2 of the present embodiment, the control unit 2C executes the process of shifting the chamber 5 from the chamber retract position to the blocking position (a chamber blocking process St11). Subsequently, in each door opening and closing apparatus 2 of the present embodiment, the control unit 2C executes a secondary chamber purge process St12 and a secondary pressure adjusting process St13, which are respectively similar to the chamber purge process St4 and the pressure adjusting process St5. Note that, it is also possible to employ the process procedure of: shifting the door part 22 from the totally open position (O) to the shifting direction switching position (P); causing the door part 22 to enter the temporary standby state at this position, and executing the chamber blocking process St11 in this state; thereafter executing the secondary chamber purge process St12 and the secondary pressure adjusting process St13; and thereafter shifting the door part 22 from the shifting direction switching position (P) to the totally closed position (C). Further, in the present embodiment, at any appropriate time point after the chamber purge process St4 is started, by stopping the supply of the environmental gas to the inner space 5S of the chamber 5, the gas use amount and the gas use time can be restricted, and a reduction in costs can be attained.

Subsequently, in each door opening and closing apparatus 2 according to the present embodiment, the control unit 2C executes the process of switching the coupling mechanism 221 from the lid coupled state to the lid coupling released state (a lid coupling releasing process St14). By this process, the coupled state between the door part 22 and the lid part 43 by the coupling mechanism 221 (the lid coupled state) can be released, and the lid part 43 can be attached to the storage container body 42. Subsequently, in each door opening and closing apparatus 2 of the present embodiment, the control unit 2C executes the process of backing off the placing pedestal 23 in the direction to be away from the frame 21 (a docking releasing process St15). Further, the control unit 2C releases the state where the storage container 4 is locked by the lock claw 232 on the placing pedestal 23 (a lock releasing process St16). Specifically, the locked state of the lock claw 232 to the lock receiving part provided at the bottom surface of the storage container 4 is released. Thus, the storage container 4 storing the transfer target objects W having undergone a predetermined process are passed from the placing pedestal 23 of each door opening and closing apparatus 2 to the storage container transfer apparatus, and transferred to the next process.

As has been described above, each door opening and closing apparatus 2 according to the present embodiment includes the pressure adjusting part 6 that causes the inner space 5S of the chamber 5 provided at the position opposing to the opening 21a on the transfer room 3 side and the inner space 4S of the storage container 4 that can be sealed by the lid part 43 to communicate with each other using a route other than the opening 21a. Therefore, by introducing the environmental gas, which has been supplied into the chamber 5 in the chamber purge process, into the inner space 4S of the storage container 4 via the pressure adjusting part 6, the pressure difference between the inner space 5S of the chamber 5 and the inner space 4S of the storage container 4 can be eliminated. Thus, as compared to the structure in which the pressure of the chamber 5 becomes higher than the pressure of the storage container 4, the force required for shifting the door part 22 toward the chamber 5 and opening the inner space 4S of the storage container 4 to the inner space 5S of the chamber 5 (the storage container opening process) can be reduced. Then, the storage container opening process can be performed smoothly and properly, and any shock associated with the storage container opening process can be prevented or suppressed. This can entirely prevent or suppress various problems such as wobbling or vibration of the entire door opening and closing apparatus 2, rising of particles, or displacement of the transfer target objects W stored in the storage container 4 on the placing pedestal 23.

In particular, in the case where the inner space 5S of the chamber 5 is filled with an environmental gas such as nitrogen gas within a short time, the pressure value to be achieved in the purge process needs to be increased to a value exceeding a predetermined value. With the conventional structure, under such a high pressure, the pressure pressing the door part 22 at the totally closed position (C) in the direction toward the storage container 4 drastically increases. This necessitates an increase also in the force for shifting the door part 22 toward the transfer room 3 (toward the chamber 5), and invites greater shock associated with the storage container opening process. Therefore, problems such as wobbling or vibration of the entire door opening and closing apparatus 2, rising of particles, or displacement of the transfer target objects W stored in the storage container 4 on the placing pedestal 23 tend to occur. However, since each door opening and closing apparatus 2 of the present embodiment includes the pressure adjusting part 6, it becomes possible to avoid an excessive pressure pressing the door part 22 at the totally closed position (C) toward the storage container 4 in the chamber purge process, and the door part 22 can be smoothly shifted toward the chamber 5. Hence, the occurrence of the above-described problems can be prevented or suppressed.

Furthermore, in the case where the structure in which the chamber 5 attains the positive pressure by the chamber purge process is employed, with the conventional door opening and closing apparatus, when the door part 22 is shifted from the totally closed position (C) to cause the inner space 4S of the storage container 4 to communicate with the inner space 5S of the chamber 5, particles may rise in the storage container 4 by an abrupt flow of the environmental gas such as nitrogen gas from the chamber 5 into the inner space 4S of the storage container 4 where the pressure is relatively low. On the other hand, with the door opening and closing apparatus 2 of the present embodiment, since the pressure adjusting part 6 can eliminate or minimize the pressure difference between the storage container 4 and the chamber 5, a sudden flow of the environmental gas from the chamber 5 into the storage container 4 can be prevented or suppressed, and rising of particles in the storage container 4 can be prevented or suppressed.

Additionally, each door opening and closing apparatus 2 according to the present embodiment can eliminate, by the pressure adjusting part 6, the pressure difference between the chamber 5 and the storage container 4 even during the purge process on the inner space 5S of the chamber 5. Therefore, it is not necessary to temporarily stop the chamber purge process for reducing the pressure of the inner space 5S of the chamber 5. Hence, the door opening and closing apparatus 2 is excellent also in terms of the purge process efficiency.

In each door opening and closing apparatus 2 according to the present embodiment, the pressure adjusting part 6 is structured using the gas discharge part 61 that discharges the environmental gas supplied to the inner space 5S of the chamber 5 to the outside of the chamber 5, the gas discharge route 62 having its upstream end coupled to the gas discharge part 61, and the gas introduction part 63 coupled to the downstream end of the gas discharge route 62, and introducing the environmental gas into the inner space 4S of the storage container 4 via the gas discharge route 62. Thus, without inviting complication of the structure, the pressure adjusting part 6 can be implemented with the relatively simple structure.

In particular, each door opening and closing apparatus 2 according to the present embodiment uses the nozzle 261, which is provided at a predetermined place on the placing pedestal 23 originally as the component that structures the bottom purge part 26 capable of replacing the gas atmosphere in the storage container 4 by the environmental gas, as the gas introduction part 63 of the pressure adjusting part 6. Accordingly, it is not necessary to newly provide a dedicated nozzle functioning as the gas introduction part 63 of the pressure adjusting part 6. Thus, the simplified structure and the reduced costs can be realized.

Further, the transfer apparatus (EFEM 1) according to the present embodiment includes the transfer room 3, the door opening and closing apparatuses 2 having the structure described above and provided on the wall surface 3A of the transfer room 3, and the transfer robot 31 provided in the transfer room 3 and capable of putting in and taking out the transfer target objects W to and from between the storage container 4 on the placing pedestal 23 of each door opening and closing apparatus 2 and the transfer room 3. Accordingly, with the above-described operation and effect of each door opening and closing apparatus 2, it becomes possible to smoothly and properly perform the storage container opening process that needs to be performed immediately before the transfer robot 31 starts to put in and take out the transfer target objects W to and from between the storage container 4 and the transfer room 3. Thus, in the environment where rising of particles and displacement of the transfer target objects W can be prevented or suppressed, the processing efficiency of the entire transfer apparatus 1 can be improved by the transfer robot 31.

Further, the method for opening the storage container 4 using the door opening and closing apparatus 2 according to the present embodiment includes the following operations. In the state where the storage container 4 whose inner space 4S is sealed by the lid part 43 is placed on the placing pedestal 23 of the door opening and closing apparatus 2, the chamber purge process is performed. Subsequently to the pressure adjusting process St5 of equalizing the pressure of the inner space 4S of the storage container 4 to the pressure of the inner space 5S of the chamber 5 by the pressure adjusting part 6, the lid part 43 is shifted together with the door part 22, whereby the inner space 4S of the storage container 4 is opened to the inner space 5S of the chamber 5 via the opening 21a of the frame 21. Accordingly, the space with which the inner space 4S of the storage container 4 communicates when the storage container 4 is opened is reduced. Even in the case where the chamber purge process is performed for maintaining the purge concentration in the storage container 4, the above-described operation and effect can be obtained. As a result, the storage container opening process can be performed smoothly and properly, and rising of particles or displacement of the transfer target objects W in the storage container 4 attributed to the shock associated with the opening process can be prevented or suppressed. By employing such a method for opening the storage container 4, the risk of a reduction in the quality of the transfer target objects W can be avoided, and a contribution to an improvement in yields can be obtained.

Note that, the present invention is not limited to the embodiment described above. For example, the embodiment exemplarily shows the structure in which among a plurality of bottom purge nozzles provided at the placing pedestal originally as the components that structure part of the bottom purge part, all the nozzles functioning as the purge gas injection nozzles are used as the gas introduction part. In place of such a structure, it is also possible to employ the structure in which not all the nozzles but a predetermined number of nozzles among the nozzles functioning as the purge gas injection nozzles are used as the gas introduction part, and the nozzles not used as the gas introduction part among the nozzles functioning as the purge gas injection nozzles are used as the purge gas injection nozzles of the bottom purge part as in the conventional manner. In this case, the purge process on the inside of the storage container can be realized by one of or both of the process of introducing the environmental gas in the chamber into the storage container by the pressure adjusting part (the process of introducing the environmental gas into the storage container by the nozzles used as the gas introduction part), and the process of allowing the bottom purge part to exhibit the intended function (the process of introducing the environmental gas into the storage container by the nozzles not used as the gas introduction part among the purge gas injection nozzles).

Furthermore, it is also possible to employ the structure in which the state is switched between a first state where among a plurality of bottom purge nozzles provided at the placing pedestal originally as the components that structure part of the bottom purge part, all of or not all but a predetermined number of nozzles functioning as the purge gas injection nozzles are used as the gas introduction part of the pressure adjusting part and a second state where the nozzles are allowed to exhibit the intended function as the bottom purge part. In this case, for example a switching valve is provided at the route (a tube or the like) directly coupled to the nozzles capable of switching between the first state and the second state, and whether the environmental gas discharged from the chamber is caused to flow toward the nozzles or the environmental gas not from the chamber but supplied from the original bottom purge-purpose environmental gas supply source is caused to flow toward the nozzles should be switched or selected.

Further, it is also possible to employ the structure in which a dedicated nozzle functioning as the gas discharge part of the pressure adjusting part is provided separately from the nozzles for the bottom purge provided on the placing pedestal. In this case, the supply route of the bottom purge part supplying the environmental gas from the bottom surface of the storage container into the storage container irrespective of the existence of the pressure adjusting part, and the supply route of the environmental gas by the pressure adjusting part into the storage container are completely separately provided.

With a storage container or a door opening and closing apparatus in which the side purge (one mode of the purge process in which the environmental gas is supplied from the side of the storage container) is employed, the purge gas injection nozzle used as the side purge part can be used as the gas introduction part of the pressure adjusting part. Further, the gas discharge part or the gas introduction part may be structured using any component or a through hole other than a nozzle.

Furthermore, as the door opening and closing apparatus, it is also possible to adopt a door opening and closing apparatus not provided with the bottom purge part supplying the environmental gas from the bottom surface of the storage container separately from the pressure adjusting part. In this case, a door apparatus capable of exhibiting the pressure adjusting function can be structured by providing any appropriate gas introduction part to the placing pedestal.

Still further, the embodiment described above exemplarily shows the mode in which the gas discharge route of the pressure adjusting part is structured by a single tube. In place of such a mode, it is also possible to couple a plurality of tubular components such as tubes whose hollow inner space can be used as channels to structure a gas discharge route. Alternatively, for example, it is also possible to use a through hole formed at any component itself, such as a through hole penetrating through the frame in the thickness direction, as part of the gas discharge route.

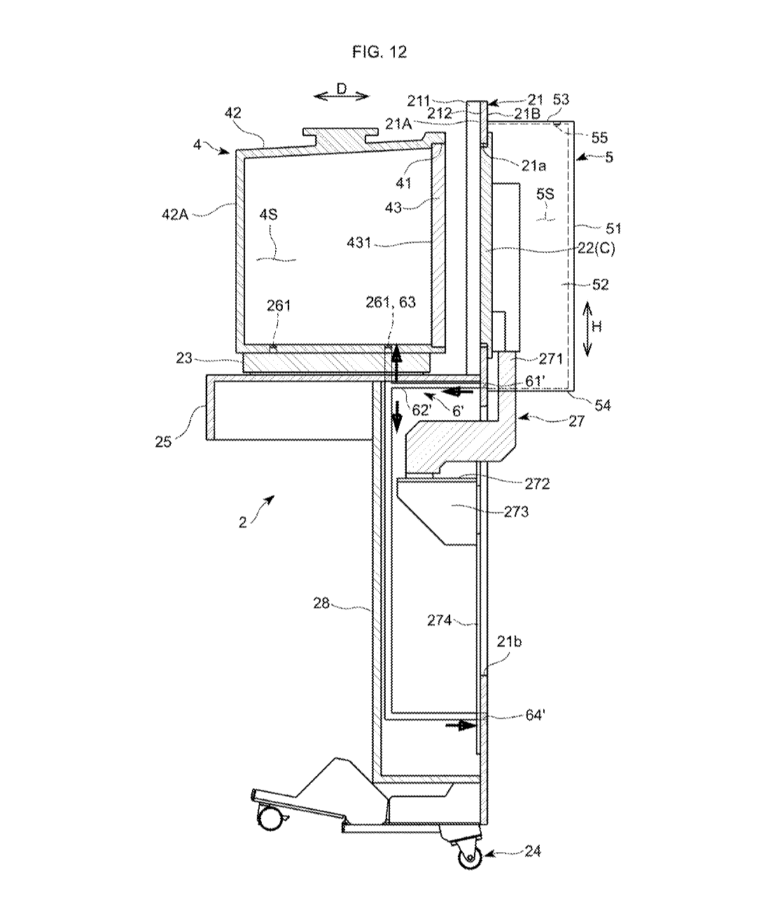

The pressure adjusting part of the present invention is just required to cause the inner space of the chamber and the inner space of the storage container to communicate with each other using a route other than the opening (the opening that can be opened or closed by the door part) formed at the frame. For example, as shown in FIG. 12, it is possible to employ a pressure adjusting part 6′ including a gas discharge part 61′ provided at the frame 21, and a gas discharge route 62′ having its upstream end coupled to the gas discharge part 61′. The gas discharge part 61′ provided at the frame 21 is a through hole communicating with the inner space 5S of the chamber 5. The upstream end of the gas discharge route 62′ is closely attached to the gas discharge part 61′. The substantial part of the gas discharge route 62′ is disposed on the inner side of the cover 28. In the gas discharge route 62′, at least the portion disposed on the inner side of the cover 28 is formed by a tube. The downstream end of the gas discharge route 62′ is closely attached to the gas introduction part 63. By such a pressure adjusting part 6′, the environmental gas supplied into the chamber 5 by the chamber purge process passes through the gas discharge part 61′, the gas discharge route 62′ and the gas introduction part 63 in this order and is introduced into the inner space 4S of the storage container 4. Accordingly, through the pressure adjusting part 6′, the pressure difference between the inner space 5S of the chamber 5 and the inner space 4S of the storage container 4 can be eliminated. Such a gas discharge route 62′ is not required to be capable of shifting or deforming following the shifting of the chamber 5. Accordingly, selection of the members structuring the gas discharge route 62′ or designing of the installation space become flexible. As shown in FIG. 12, it is possible to employ, as the gas discharge route 62′, the structure having a route for causing the environmental gas in the chamber 5 from the gas discharge part 61′ to flow toward any appropriate discharge space (for example, the inner space of the transfer room) (the discharge route), in addition to a route for causing the environmental gas in the chamber 5 from the gas discharge part 61′ to flow toward the gas introduction part 63 (the pressure adjusting route). In FIG. 12, the downstream end of the discharge route is closely attached to a through hole 64′ provided at the position in the frame 21 where the inner space of the cover 28 and the inner space of the transfer room communicate with each other. In this case, the discharge route of the environmental gas in the chamber 5 flowing from the gas discharge part 61′ should be capable of being switched to either the pressure adjusting route or the discharge route (for example, the structure in which a switching valve is disposed). Note that, the gas discharge route 62′ can shift or deform following the shifting of the placing pedestal 23.

Further, the chamber is just required to be capable of forming an inner space in the sealed state or in the substantially sealed state relative to the frame or the door part, as being positioned at the blocking position. For example, when the chamber is shifted between the blocking position and the chamber retract position, the portion that actually shift (the movable portion) may be the entire chamber, or may be a predetermined portion of the chamber including the upright wall that can face the opening of the frame (as one example, the portion except for the upper wall). That is, it is possible to employ the structure in which part of the chamber is fixed to the frame.

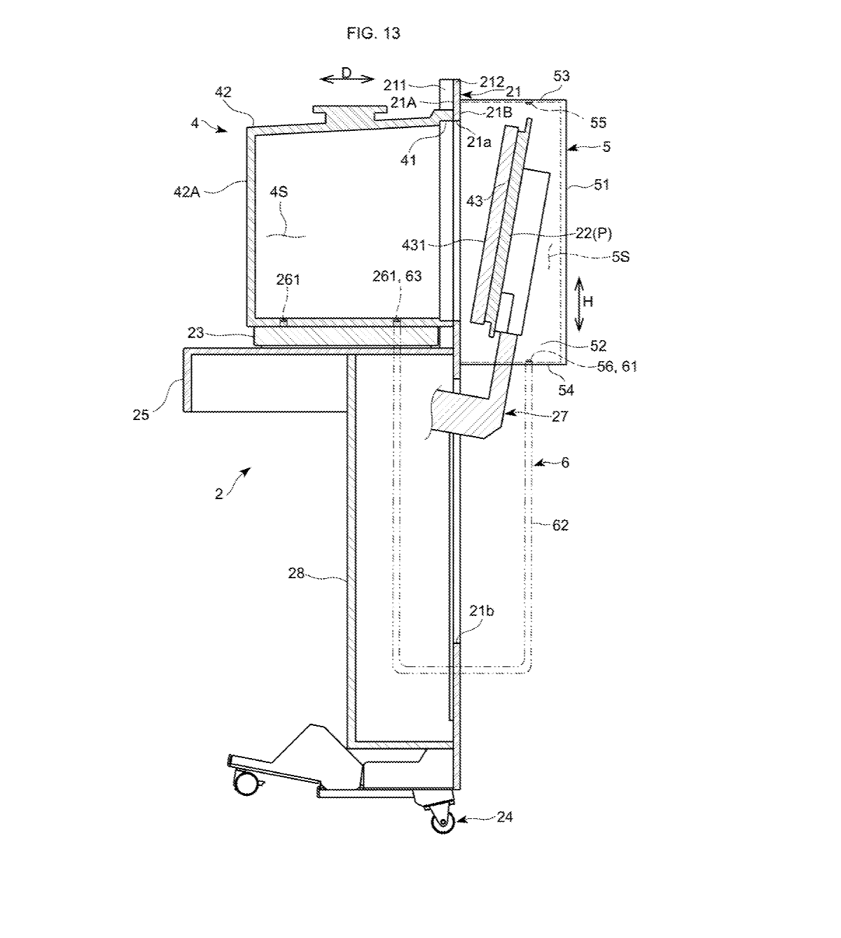

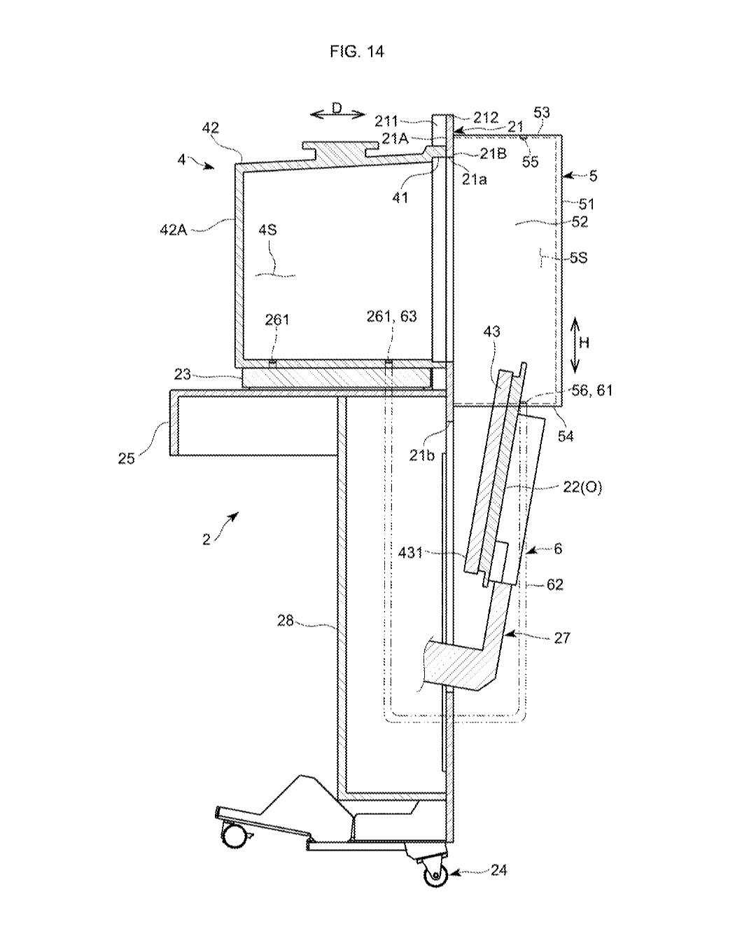

Further, the door part may perform a rotation operation during the entire or part of shifting between the totally closed position and the totally open position. For example, as shown in FIGS. 13 and 14, the door part 22 may be set to linearly shift between the shifting direction switching position (P) and the totally open position (O), while being set to rotationally shift between the totally closed position (C) and the shifting direction switching position (P). In this case, the attitude of the door part 22 positioned at the shifting direction switching position (P) is tilted by a predetermined angle. The door part 22 shifts between the shifting direction switching position (P) and the totally open position (O) while maintaining this tilt attitude. Note that, the specific structure or the drive source of the door shifting mechanism 27 which are not partially shown in FIGS. 13 and 14 can be changed as appropriate.

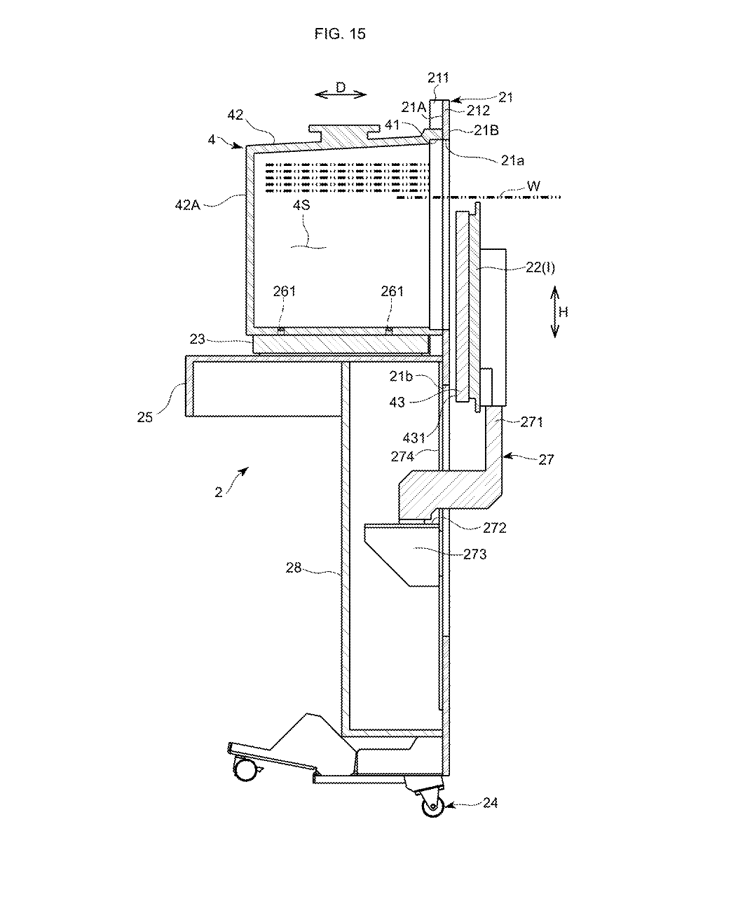

Further, the embodiment described above exemplarily shows the mode in which the door part is on standby at the totally open position during the process of putting in and taking out the transfer target objects. In place of such a mode, for example as shown in FIG. 15, it is also possible to cause, during the process of putting in and taking out the transfer target objects W, the door part 22 to be on standby at an intermediate opening position (I) where the inner space 4S of the storage container body 42 is opened just by the amount required for putting in or taking out the transfer target objects W to and from the storage container 4. With such a structure, the opening degree of the inner space 4S of the storage container body 42 in the height direction during the process of putting in and taking out the transfer target objects W can be effectively reduced. Further, at the time point where the inner space 4S of the storage container body 42 is opened, the purge concentration in the storage container 4 temporarily reduces and the moisture concentration increases. Here, the time required for the increased moisture concentration to recover a predetermined low-value moisture concentration can be reduced. Still further, as compared to the mode in which the door part 22 is shifted between the totally closed position (C) and the totally open position (O), it is also advantageous in that the shift stroke of the door part 22 can be shortened. Note that, depending on the setting of the totally open position (O), the intermediate opening position of the transfer target object W stored in the lowermost stage in the storage container 4 during the putting in and taking out process may become identical to or substantially identical to the totally open position (O). Note that, FIG. 15 does not show the chamber.

As has been described above, the door opening and closing apparatus of the present invention can structure part of the EFEM as one example of the transfer apparatus. Accordingly, it is also possible to use the door opening and closing apparatus that structures part of a transfer apparatus other than the EFEM or part of a sorter apparatus. The sorter apparatus is an apparatus in which, for example, a plurality of the door opening and closing apparatuses of the present invention are disposed along the wall surface of a transfer room, and transfer target objects can be exchanged by a transfer robot provided in the transfer room between storage containers respectively placed on the placing pedestals of the door opening and closing apparatuses. The sorter apparatus may be a sorter apparatus in which a plurality of door opening and closing apparatuses are disposed along the common wall surface of the transfer room. Alternatively, the sorter apparatus may be a sorter apparatus in which one or a plurality of door opening and closing apparatuses are each disposed at different wall surfaces of the transfer room (for example, opposing wall surfaces such as the front wall and the rear wall). Still further, the sorter apparatus may be a sorter apparatus in which a buffer station or an aligner is disposed at any of the side surfaces, and the transfer target objects can be exchanged, put in or taken out by the transfer robot among the storage containers respectively placed on the placing pedestals of the door opening and closing apparatuses, or between the storage containers and the buffer station or the aligner.

With such sorter apparatuses, by virtue of provision of the door opening and closing apparatuses having the structure described above, the operation and effect described above can be obtained, and the process of putting in and taking out the transfer target object can be performed suitably.

The door opening and closing apparatus disposed on the wall surface of the transfer room may be one in number.

In the embodiment described above, wafers are exemplarily shown as the transfer target objects. However, the transfer target objects may be reticles, liquid crystal substrates, glass substrates, culture plates, culture vessels, dishes, or petri dishes. That is, the present invention is applicable to the transfer technique of any transfer target objects stored in a container in various fields such as semiconductors, liquid crystals, cell cultivations and the like.

Further, the door opening and closing apparatus of the present invention is not limited to a load port, and can be used as the interface portion between the storage container and the transfer room.

As the purge process in the storage container, in addition to the bottom purge process, it is also possible to employ a so-called front purge process, in which an environmental gas is supplied from the front side of the inner space of the storage container in the state where the inner space of the storage container is opened frontward (toward the chamber). A front purge part with which the front purge process is executed may be provided at the storage container body, the lid body, or the door opening and closing apparatus. The storage container of the present invention may be, as described in the embodiment, a storage container to which the purge process is carried out at any timing after the time point where the storage container is placed on the placing pedestal of the door opening and closing apparatus. However, the storage container of the present invention may be a storage container to which the purge process is not carried out at any timing after the time point where the storage container is placed on the placing pedestal of the door opening and closing apparatus, or a storage container to which the purge process is previously carried out at the time point before the storage container is placed on the placing pedestal. Specific examples of the timing of the purge process previously carried out at the time point before the storage container is placed on the placing pedestal of the door opening and closing apparatus include the time point where the storage container is stored in a storage capable of storing a plurality of storage containers, the time point where the storage container is placed on a dedicated purge station other than the door opening and closing apparatus, the time point during the manufacturing process in other transfer target object manufacturing apparatus or after the manufacture and the like.

The genre or type of the storage container, the specific structure or functions of the transfer room can be also changed as appropriate. As the environmental gas required for performing the purge process, any gas other than nitrogen gas and dry air may be employed.

The transfer robot may be a transfer robot having a plurality of transfer target object gripping parts (the hands in the embodiment). Further, it may be a transfer robot whose transfer target object gripping part is structured by a predetermined component or the like other than the hand. Further, the transfer robot is just required to be disposed in the transfer room. The door opening and closing apparatus may include the transfer robot.

The embodiment exemplarily shows the mode in which the door opening and closing apparatus 2 includes the control unit 2C, and the control unit 2C controls the actuation of the constituent members such as shifting of the door part 22. In place of this mode, it is also possible to employ the mode in which a control unit (a control unit 3C of the entire EFEM or a control unit MC of the processing apparatus M being the higher-level controllers) that controls the actuation of a higher-level apparatus than the door opening and closing apparatus (the EFEM or the processing apparatus in the embodiment) also controls the actuation of the door opening and closing apparatus.

Further, the control unit is not limited to the dedicated system, and can be realized by a normal computer system. For example, by installing, from a recording medium (a flexible disc, a CD-ROM and the like) storing a program for executing the above-described process, the program in a general-purpose computer, the control unit executing the process can be structured. Any means for supplying such a program can be employed. In addition to supplying via a predetermined recording medium as described above, for example the program may be supplied via a communication line, a communication network, a communication system and the like. In this case, for example, the program may be posted on a bulletin board system (BBS) of a communication network, and the program may be provided as being superimposed on carrier wave via the network. Then, by activating the program supplied in this manner and executing the program similarly to other application programs under control of OS, the above-described process can be executed.

In addition, the specific structure of the constituent members is not limited to those in the embodiment, and various modifications can be made within the scope not deviating from the spirit of the present invention.

What is claimed is:

1. A door opening and closing apparatus provided adjacent to a transfer room for putting in and taking out a transfer target object to and from between a storage container capable of storing the transfer target object in an inner space thereof and the transfer room, the door opening and closing apparatus comprising:
a plate-like frame that structures part of a wall surface of the transfer room and provided with an opening for opening the transfer room;
a door part capable of opening and closing the opening;
a placing pedestal on which the storage container can be placed;
a chamber having an inner space to be subjected to a purge process with an environmental gas; and
a pressure adjusting part,
wherein the chamber is provided at a position on the transfer room side so as to face the opening, and
the pressure adjusting part causes the inner space of the chamber and the inner space of the storage container to communicate with each other using a route other than the opening.

2. The door opening and closing apparatus according to claim 1, wherein
the pressure adjusting part includes
a gas discharge part configured to discharge the environmental gas supplied into the inner space of the chamber to an outside of the chamber,
a gas discharge route having an upstream end coupled to the gas discharge part, and
a gas introduction part coupled to a downstream end of the gas discharge route and configured to introduce the environmental gas into the inner space of the storage container via the gas discharge route.

3. The door opening and closing apparatus according to claim 1, further comprising
a bottom purge part capable of replacing a gas atmosphere in the storage container by the environmental gas using a plurality of nozzles provided at predetermined positions on the placing pedestal,
wherein the gas introduction part is structured by a dedicated nozzle, the dedicated nozzle being separately provided from the nozzles of the bottom purge part.

4. The door opening and closing apparatus according to claim 1, further comprising
a bottom purge part capable of replacing a gas atmosphere in the storage container by the environmental gas using a plurality of nozzles provided at predetermined positions on the placing pedestal, wherein
among the plurality of nozzles, a predetermined number of nozzles function as the gas introduction part.

5. A transfer apparatus for transferring a transfer target object, the transfer apparatus comprising:
a transfer room into which the transfer target object is transferred;
a door opening and closing apparatus provided on a wall surface of the transfer room; and
a transfer robot provided in the transfer room, the transfer robot being capable of putting in and taking out the transfer target object to and from between a storage container placed on a placing pedestal of the door opening and closing apparatus and the transfer room,
wherein the door opening and closing apparatus is used for putting in and taking out the transfer target object to and from between the storage container capable of storing the transfer target object in an inner space thereof and the transfer room, the door opening and closing apparatus including:
a plate-like frame that structures part of the wall surface of the transfer room and is provided with an opening for opening the transfer room;
a door part capable of opening and closing the opening;
the placing pedestal on which the storage container can be placed;
a chamber having an inner space to be subjected to a purge process with an environmental gas; and
a pressure adjusting part,
wherein the chamber is provided at a position on the transfer room side so as to face the opening, and
the pressure adjusting part causes the inner space of the chamber and the inner space of the storage container to communicate with each other using a route other than the opening.

6. A storage container opening method for opening, by the door opening and closing apparatus according to claim 1, a storage container having an inner space sealed by a lid part, the method comprising
shifting the lid part together with the door part and opening the inner space of the storage container to the inner space of the chamber via the opening, in a state where the storage container is placed on the placing pedestal of the door opening and closing apparatus,
wherein in a state where the inner space of the storage container is sealed, a purge process is performed with an environmental gas to the inner space of the chamber,
the environmental gas in the chamber is introduced into the inner space of the storage container, from the inner space of the chamber having undergone the purge process, by the pressure adjusting part using the route other than the opening, to equalize a pressure of the inner space of the storage container to a pressure of the inner space of the chamber by a pressure adjusting process, and subsequently
the lid part is shifted together with the door part, to cause the inner space of the storage container to open to the inner space of the chamber via the opening.
